(19) United States
(12) Patent Application Publication
(10) Pub. No.: US 2026/0280227 A1
(43) Pub. Date: Sep. 17, 2026

(54) HEAT MANAGEMENT OF SEMICONDUCTOR DEVICES USING SUBSTANTIALLY TWO-DIMENSIONAL MATERIALS

(71) Applicant: Mellanox Technologies, Ltd., Yokneam (IL)

(72) Inventors: Oren STEINBERG, Tal Shahar (IL); Ella SANDERS, HaSolelim (IL); Filip Leonard HJORT, Partille (SE); Uziel KOREN, Haifa (IL); Anders LARSSON, Hovas (SE); Isabelle CESTIER, Haifa (IL); Elad MENTOVICH, Tel Aviv (IL)

(21) Appl. No.: 19/078,715

(22) Filed: Mar. 13, 2025

(51) Int. Cl. H01S 5/028; H01S 5/024; H01S 5/183

(52) U.S. Cl. CPC H01S 5/0282; H01S 5/02469; H01S 5/18344

(57) ABSTRACT

In various embodiments, heat-managed (HM) devices, arrays of HM devices, and method for fabricating HM devices are provided. An HM device of an example embodiment includes a semiconductor device comprising III-V semiconductor material; and a film of a thermally conductive material disposed directly in thermal communication with semiconductor material of the semiconductor device. Operation of the semiconductor device generates heat and the film provides a thermal path for transporting thermal energy away from the semiconductor device.

### BACKGROUND

As artificial intelligence and/or machine learning use increases, the amount of information being communicated between large clusters of computing resources (e.g., graphical processing units (GPUs), central processing units (CPUs), data processing units (DPUs), and/or the like) is also increasing. Links between computing resources and/or chips thereof are based on copper cables (short reach) or optical cables. In the optical cables, the data to be transferred between chips (or switches) is encoded/decoded from electrical to optical signal (and vice versa) and conveyed via an optical fiber. To enable large bandwidth communications, transceivers may include arrays of semiconductor devices (e.g., vertical cavity surface emitting lasers (VCSELs); distributed-feedback (DFB) lasers; light emitting diodes (LEDs); modulators such as electro-absorption modulators, intensity and/or phase modulators, and other modulators; electro-absorption modulated lasers (EML); and/or the like) configured to generate optical signals and/or array of semiconductor devices (e.g., photodiodes) configured for receiving optical signals.

Such semiconductor devices often include III-V semiconductor materials, which tend to poor heat conductivity. Additionally, the contact between semiconductor devices formed from III-V semiconductor materials (e.g., VCSELs, DFB lasers, LEDs, photodiodes or other diodes, and/or the like) and the substrate the semiconductor devices are mounted to tends to be small (e.g., with respect to the ratio of areas between the active part of the semiconductor device where most of the heat tends to be generated and the entire device area of the substrate). This makes it difficult to achieve efficient thermal contact which can improve heat dissipation. Therefore, heat management of these devices is difficult for individual semiconductor devices and compounded in arrays of such devices. Therefore, there is a need in the art for techniques, and corresponding semiconductor devices and/or arrays of semiconductor devices, for improved heat management.

### GENERAL DESCRIPTION

Datacenters rely on a fast and robust communication infrastructure. This is achieved by using optical interconnects, especially between different server racks. Each physical link employing a single optical fiber may include multiple communication channels, which are distinguished by different wavelengths in wavelength division multiplexing (WDM) systems. Such optical interconnects tend to include transceivers that are in optical communication with one another via one or more optical fibers. A transceiver includes one or more optical signal generating components and/or one or more optical signal detecting components. For example, a transceiver may include one or more semiconductor devices (e.g., vertical cavity surface emitting lasers (VCSELs); distributed-feedback (DFB) lasers; light emitting diodes (LEDs); modulators such as electro-absorption modulators, intensity and/or phase modulators, and other modulators; electro-absorption modulated lasers (EML); and/or the like) configured to generate optical signals and/or one or more semiconductor devices (e.g., photodiodes) configured for detecting optical signals.

Semiconductor surface emitting devices such as vertical cavity surface emitting lasers (VCSELs) and micro-LEDs and others have major advantages such as high light extraction efficiency, small footprint, excellent scalability, high modulation bandwidth, and low-cost manufacturing. However, these devices lack proper heat extraction mechanisms. This is due to their basic configuration: the physical contact between the device and the substrate is substantially small, e.g. compared to edge emitting devices (such as a DFB laser). Moreover, the active region, where the heat is generated, is usually relatively far from the substrate, being separated from this substrate by many layers, such as distributed Bragg reflectors (DBRs) which also contribute to heat generation due to high electrical resistance. Finally, since III-V semiconductor materials display relatively poor heat conductivity (e.g. GaAs thermal conductivity coefficient is 55 W/m K), heat is accumulated within the device and deteriorates its performance and device lifetime. Currently, the state of the art for heat removal is either to mount these devices such as VCSELs and VCSELs arrays directly, or with a highly heat conductive heat-spreader, on a copper heat-sink. Recently, to further improve heat extraction, new VCSEL designs have been proposed by employing diamond heat spreaders top and/or bottom by bonding. However, for both approaches, heat must diffuse through the whole structure to reach the bottom or the top of the device, from where it can be extracted. For high power devices or multiple VCSEL/LED arrays these approaches are not sufficient and more efficient heat extraction has to be provided.

According to various embodiments, a semiconductor device is an electrical, optical, or electro-optical device that includes semiconductor material, such as III-V semiconductor material. Some non-limiting examples of semiconductor devices include VCSELs, DFB lasers, LEDs, photodiodes or other diodes, or power transistors. Various embodiments provide a heat managed (HM) device comprising a semiconductor device comprising III-V semiconductor material. The HM device further includes a film of a thermally conductive material disposed directly in thermal communication with semiconductor material of the semiconductor device. For example, the film may be in direct physical contact with semiconductor material of the semiconductor device. For example, the film may be disposed directly on a perimeter of the semiconductor device, on at least a portion of an (narrow) end of a mesa of the semiconductor device, and/or on another semiconductor material surface of the semiconductor device. Operation of the semiconductor device generates heat. The film provides a thermal path configured to channel the heat away from the semiconductor device (e.g., to a heat sink and/or the like). For example, the film may be in thermal communication with multiple HM devices, a substrate hosting one or more HM devices, a heat sink, and/or the like. The application of the film enables heat spreading from active power devices and dense active devices (such as VCSELs arrays) into heat sinks or other surfaces in order to reduce hot spots. The film operates as a heat removing material and may be embedded in the semiconductor light emitting devices so that each region of the device is in close contact with the film layer to maximize heat transfer efficiency.

In an example embodiment, the film consists of a first film that is thermally conductive and electrically non-conductive and configured to be in direct contact with the semiconductor material of the semiconductor device. In an example embodiment, the film comprises a first film that is thermally conductive and electrically non-conductive and a second film that is thermally conductive, and the first film is in direct contact with the semiconductor material of the semiconductor device. In some embodiments, the thermally conductive material is electrically non-conductive and the film may be a passivation layer on the semiconductor device. For example, the film may be in direct contact with a perimeter of the semiconductor material of the semiconductor device. In certain embodiments, the thermally conductive material is a dielectric material or an electrically non-conductive material. For example, in some embodiments, the thermally conductive material is and/or comprises two-dimensional hexagonal boron nitride (2D h-BN). In various embodiments where the semiconductor device or array of semiconductor devices is configured to generate or detect electro-magnetic radiation, the film may be formed of a material that is transparent to electro-magnetic radiation characterized by an intended wavelength of operation of the semiconductor device(s). In various embodiments, the film has a thickness in a range of one atomic layer to 300 nm. In various embodiments, the film is in thermal communication with a heat sink. In certain embodiments, the film has an in-plane thermal conductivity coefficient of at least 400 Watts per meter-Kelvin (W/m*K). In certain embodiments, a topology of the film is defined by a topology of the semiconductor device.

According to another aspect, an array of devices is provided. In an example embodiment, the array of devices includes an array of a plurality of semiconductor devices. Each semiconductor device or at least some of the semiconductor devices of the plurality of semiconductor devices has a film of a thermally conductive material disposed directly in thermal communication with semiconductor material of the semiconductor device. For example, the film may be in direct physical contact with semiconductor material of the semiconductor device. For example, the film may be disposed directly on a perimeter of the semiconductor device, on at least a portion of an end of a mesa of the semiconductor device, and/or on another semiconductor material surface of the semiconductor device. This causes the film to be placed as close as possible to the heat source of the device such that the heat may be efficiently transported away from the device(s) via the thermal path provided by the film. Operation of a semiconductor device of the plurality of semiconductor devices generates heat and the film may provide a thermally conductive path configured to channel heat away from the semiconductor devices (e.g., to a heat sink and/or the like).

In an example embodiment, the plurality of semiconductor devices comprise at least one of a vertical cavity surface emitting laser (VCSEL); distributed-feedback (DFB) laser; light emitting diode (LED); diode; modulator such as an electro-absorption modulator, intensity and/or phase modulator, and other modulator; electro-absorption modulated laser (EML); or a power transistor. In an example embodiment, the film comprises a first film that is thermally conductive and electrically non-conductive and a second film that is thermally conductive, and the first film is in direct contact with the semiconductor material of the semiconductor device. In some embodiments, the thermally conductive material is electrically non-conductive and the film is a passivation layer on the semiconductor device to protect the semiconductor from defects and to minimize the leakage current characteristics. In various embodiments, the thermally conductive material is two-dimensional hexagonal boron nitride (2D h-BN). In certain embodiments, the film has a thickness in a range of one atomic layer to 300 nm. In various embodiments, the array of devices in in thermal communication with a heat sink via the film. In some embodiments, the film has an in-plane thermal conductivity coefficient of at least 400 W/m*K.

According to another aspect, a method for fabricating a device is provided. In an example embodiment, the method includes fabricating one or more semiconductor components of a semiconductor device. Fabricating the one or more semiconductor components semiconductor device comprises defining a perimeter of the semiconductor device. The method further includes transferring a film of thermally conductive material onto a surface of semiconductor material of the semiconductor device.

In an example embodiment, transferring the film of thermally conductive material onto the perimeter of the semiconductor device transfers a topology of the semiconductor device to the film. In an example embodiment, the method further includes growing the film on a foil, covering the film with poly(methyl methacrylate) (PMMA), and removing (etching) the foil. In an example embodiment, the method further includes, after transferring the film to the perimeter of the semiconductor device, removing the PMMA. In an example embodiment, the method further includes at least one of depositing Benzocyclobutene (BCB) or another structural material on the film or performing a lithographic process. After transferring the film to the semiconductor surface, it can be patterned and etched to create openings for metals and other materials, integrating it into the VCSEL or other semiconductor device structure.

Various embodiments provide optical interconnects that each include devices and/or arrays of devices of various embodiments. The optical interconnects may be configured to connect between chips or between different communication systems. For example, it might provide optical interconnecting for network interface controller (NIC) to switch, switch to switch, and/or chip to chip. Optical interconnects can be used in a variety of applications, such as switches, processing units (e.g., graphics processing units (GPUs), etc.). An optical interconnect can include an optical link (e.g., optical fiber) to transmit an optical signal. Optical interconnect bandwidth can be scaled by transmitting an optical signal including multiple wavelengths using the same optical link. In doing so, the transmitter is tuned to generate the optical signal including multiple carrier wavelengths (e.g., possibly via an array of devices comprising a plurality of VCSELs, DFB lasers, LEDs, modulators, EMLs and/or the like). Moreover, each modulator of a modular array can be tuned to receive and modulate a respective carrier frequency. Ordering the multiple wavelengths can be important to ensure that the transmitter and receiver are properly communicating data contained within the optical signal.

In at least one example embodiment, the optical interconnect is part of a datacenter that corresponds to a collection of network devices, such as network switches (e.g., Ethernet switches, IP routers, multiservice platforms, various transmission network elements, legacy communication equipment, or in any other suitable communication system) connected with a collection of servers or compute nodes. A switch fabric serves to transfer the data between the switch ports. A switch fabric comprises one or more interconnect circuits, which may be arranged in various switch fabric architectures, e.g., m*m crossbar, Banyan, Benes, Omega, Clos, multi-plane, STS, TST, shared memory, buffered crossbar, any other suitable blocking or non-blocking architecture, or any applicable mixed architecture thereof. A switch fabric is realized in typical embodiments by hardware, which may comprise Field-Programmable Gate Arrays (FPGAs) and/or Application-Specific Integrated Circuits (ASICs), and in some implementations also bus interconnects. The datacenter may adhere to a networking topology (e.g., a hierarchal networking topology), such as a fat tree topology, a Slim Fly topology, a Dragonfly topology, and/or the like. The datacenter routes traffic amongst the network switches and servers therein, and at least one layer of the topology in the datacenter is coupled to the communication network to allow networking traffic to flow between the datacenter and the network device(s).

The optical interconnect may include a substrate and an electro-optical component (VCSEL, photodiode, etc.) supported by the substrate and configured to convert between electrical and optical signals. The optical interconnect may further include a transmission block defining a receiving surface configured to receive an optical fiber, and a waveguide configured to transmit optical signals between the electro-optical component and the receiving surface such that in an operational configuration in which the receiving surface receives an optical fiber, the electro-optical component and the optical fiber are in optical communication.

While the present disclosure illustrates and describes the optical interconnect without a housing or other protective casing, as would be understood by one of ordinary skill in the art in light of the present disclosure, some or all of the optical interconnect may be supported or enclosed by any housing used in communications systems to protect the components supported therein (e.g., as part of Quad Small Form-factor Pluggable (QSFP) connectors, Small Form Pluggable (SFP) connectors, or the like). Furthermore, the substrate hosting the electro-optical component may be substantially rectangular shape and/or may be dimensioned (e.g., sized and shaped) for use in any communication system regardless of geometric constraints (e.g., L-shaped, squared-shaped, etc.).

In various embodiments, an optical interconnect for receiving an optical fiber may be implemented in a flip-chip configuration. In certain embodiments, the optical interconnect is configured as a flip-chip component such that a longitudinal axis of the first adiabatic transition profile of the optical interconnect and a longitudinal axis of the second adiabatic transition profile of the optical interconnect may be collinear. Said differently, the orientation of the optical interconnect in such an embodiment does not require a mirror or other reflective surface to redirect optical signals between the electro-optical component and the receiving surface. As would be evident to one of ordinary skill in the art in light of the present disclosure, however, the optical interconnect in a flip-chip configuration may also include one or more mirrors (e.g., reflective surfaces) to accommodate optical fibers received at varying angles. In some optical interconnect embodiments, only mirrors may be operationally configured to redirect light given that at some bending radii, light may remain confined to the waveguide. Accordingly, embodiments of a field replaceable modular optical interconnect unit are described that are configured to be received by a main switch system box. The field replaceable modular optical interconnect unit comprises a housing comprising at least a front panel, a rear panel, and side panels extending between the front and rear panels, a printed circuit board assembly supported within the housing, an optical module supported on the printed circuit board assembly and configured to convert between optical signals and corresponding electrical signals for respectively transmitting or receiving optical signals through a fiber optic cable, a board-to-board connector disposed on the rear panel of the housing and configured to enable electrical signals to be transmitted between the printed circuit board assembly and a main switch system box, and an external connector disposed on the front panel of the housing and configured to engage an external optical fiber for transmitting optical signals between the optical module and an external component. The field replaceable modular optical interconnect unit may be configured to be electrically connected to the main switch system box via engagement of the board-to-board connector with a corresponding connector of the main switch system box when the housing is received by the main switch system box.

In some embodiments, the optical module may be a mid-board optical module (MBOM), and/or the field replaceable modular optical interconnect unit may comprise a plurality of external connectors. For example, the external connector may be a first external connector, and the field replaceable modular optical interconnect unit may further comprise a second external connector disposed on the front panel of the housing and configured to enable transmission of electrical signals between the printed circuit board assembly and an external component connected thereto.

In a typical optical interconnect Vertical Cavity Surface Emitting Laser (VCSEL) diodes are utilized as light emitters to transmit binary or digital data over optical fibers. However, the light source may in principle be any suitable light source and the transmitted waveform may be any suitable waveform for transmitting information. Most light emitters have a threshold current above which they substantially begin to emit light. Increasing the current driven through the emitter from zero to above said threshold may be time consuming, and therefore a bias current is typically driven through the light source. The bias current can be set just below, at the threshold, or above the threshold, but it also is often set to be well above threshold. This bias current is often programmable so as the same circuit design may be utilized to drive different light emitters and/or be used for different applications. Additional time varying current which modulates the emission from the light emitter is referred to as the modulation current.

In some embodiments, the disclosed technique provides an electro-optical (EO) interconnect assembly comprising a pair of pluggable EO transceivers connected at respective ends of an optical fiber. The EO transceivers are typically used to connect network-connected devices (e.g., remote client switches, network adapters such as Network Interface controllers (NICs) and Host Channel Adapters (HCAs), Smart-NICs (NICs having embedded CPUs), network-enabled Graphics Processing Units (GPUs), and the like). The terms “network-connected device” and “network device” are used interchangeably herein. In certain embodiments, an optical interconnect includes a substrate, one or more optical waveguides, one or more first micro-lenses, one or more second micro-lenses, and first and second mechanical fixtures.

The present disclosure describes heat-managed (HM) devices including semiconductor devices having a film of a thermally conductive material disposed on a perimeter thereof, arrays of such HM devices, and/or methods for fabricating such HM devices. The film may be positioned on sidewalls, top emission areas, at least a portion of an (narrow) end of a mesa of a semiconductor device, and/or flip-chip configurations, to enhance heat transfer. In some embodiments, the HM devices or arrays of HM devices may be incorporated into optical interconnects (e.g., as optical signal generating components, optical signal detecting components, and/or the like). Various embodiments relate to interconnects (e.g., interconnect topologies) that are scalable and advantageous for networks that require a large number of all-to-all or point-to-point links between one or more node or send/receive pairs. In particular, silicon photonics interconnects or topologies are provided herein that may achieve at least moderate bandwidth between many nodes with physical, optical fiber connections. In some implementations, the one or more node or send/receive pairs are coupled with an optical fiber allowing a single wavelength to pass therebetween. In other implementations, multiple wavelengths or groups of wavelengths may be transmitted or received by nodes while simultaneously passing multiple wavelengths or groups of wavelengths to other nodes via optical fiber loops connecting three or more nodes. In some implementations, such interconnects as described herein do not rely on or include one or more of the following: wavelength synchronization between transmit and receive pairs, arbitration of the fiber(s), demultiplexers on the receiver side, and/or an optical crossbar. In some implementations, the optical interconnects may be sized to fit a face-plate form factor or as a mid-board optical connector or co-packaged optics. In some embodiments, the present disclosure provides optical interconnects for high bandwidth density applications like switches and GPUs or other processing elements. In one example, the processing elements may include central processing units (CPUs), graphics processing units (GPUs), data processing units (DPUs), quantum processing units (QPUs), a plurality of parallel processing units (PPUs), and application-specific integrated circuits (ASICs). QPUs are configured to perform one or more operations associated with a quantum algorithm. In some embodiments, each of the one or more QPUs may include a plurality of qubits and the one or more QPUs may be in communication with each other via a quantum channel. In some embodiments, each of the plurality of qubits may include local qubits, global qubits, and/or synchronization qubits. In some embodiments, the local qubits of each QPU may be configured to perform the one or more operations associated with the quantum algorithm on the QPU that the local qubits are associated with.

A “node” as described herein may refer to a network switch to which a plurality of computer processing units (CPUs), graphical processing units (GPUs), data processing units (DPUs), or memory media are connected in an arbitrary number. The network switch may communicate with other network switches of the same kind to which the same processor and memory units may be connected. However, in other implementations, “node” may also refer to a processor which may be responsible for communication with all other nodes in the network or subnetwork.

An “optical fiber” as described herein can refer to a single optical fiber (e.g., including a core and a cladding) to provide unidirectional optical communication, can refer to a bidirectional pair of optical fibers (e.g., each including a core and a cladding) to provide both transmit and receive communications in an optical network, or can refer to a multi-core fiber, such that a single cladding could encapsulate a plurality of single-mode or multi-mode cores. Optical fibers can extend contiguously and uninterrupted between node or send/receive pairs (e.g., via pass-through connections) or include two or more fibers connected via fiber-to-fiber connections such that the fibers function or perform as a single fiber.

Silicon Photonics (SiP) is a technology that enables optical systems to be manufactured using silicon processes with silicon as the optical medium. Various optical components, such as interconnects and signal processing components, may be fabricated and integrated in a single SiP device. Some SiP devices are fabricated on a silica substrate or over a silica layer on a silicon substrate, a technology that is often referred to as Silicon on Insulator (SOI). In certain optical systems, a SiP device is attached to an external device to facilitate optical communications. However, it is generally difficult to accurately align light signals on the SiP with an external device that receives the light.

In certain optical systems, a SiP device is attached to an external device to facilitate optical communications. For example, the system includes one or more waveguides that carry light signals to and/or from optical chips. Examples of optical chips that can be included on the device include, but are not limited to, one or more components selected from a group consisting of facets through which light signals can enter and/or exit a waveguide, entry/exit ports through which light signals can enter and/or exit a waveguide from above or below the device, multiplexers for combining multiple light signals onto a single waveguide, demultiplexers for separating multiple light signals such that different light signals are received on different waveguides, optical couplers, optical switches, lasers that act as a source of a light signal, amplifiers for amplifying the intensity of a light signal, attenuators for attenuating the intensity of a light signal, modulators for modulating a signal onto a light signal, modulators that convert a light signal to an electrical signal, and vias that provide an optical pathway for a light signal traveling through the device. Additionally, the device can optionally, include electrical components. For instance, the device can include electrical connections for applying a potential or current to a waveguide, controlling active optical components, such as modulators, for example, and/or for controlling other components on the optical device.

### BRIEF DESCRIPTION OF THE SEVERAL VIEWS OF THE DRAWINGS

Reference will now be made to the accompanying drawings, which are not necessarily drawn to scale, and wherein:

FIG. 1 provides a schematic cross-sectional diagram of an example heat-managed (HM) device, in accordance with certain embodiments;

FIG. 1A provides a schematic cross-sectional diagram of a multi-level film in direct physical contact with semiconductor material of a semiconductor device, in accordance with certain embodiments;

FIG. 1B provides a schematic cross-sectional diagram of a single level film in direct physical contact with a semiconductor device, in accordance with certain embodiments;

FIG. 2 provides a schematic cross-sectional diagram of an example flip-chip mounted HM device, in accordance with certain embodiments;

FIG. 3A provides a schematic cross-sectional diagram of an example HM device including a dielectric distributed Braff reflector (DBR), in accordance with certain embodiments;

FIG. 3B provides a schematic cross-sectional diagram of an example flip-chip mounted HM device including a dielectric DBR, in accordance with certain embodiments;

FIG. 4 illustrates simulated data of the temperature distribution of a conventional VCSEL array;

FIG. 5 provides a top view diagram of an array of HM devices, according to certain embodiments;

FIG. 6 provides a schematic cross-sectional diagram of a portion of an array of flip-chip mounted HM devices, in accordance with certain embodiments;

FIG. 7 provides a flowchart illustrating various processes, procedures, and/or operations for fabricating an HM device, according to certain embodiments;

FIG. 8 provides a block diagram of an optical interconnect including arrays of HM devices, according to certain embodiments;

FIG. 9 provides a block diagram of an example system that may include one or more optical interconnects including HM devices according to certain embodiments;

FIG. 10 provides a schematic diagram of an example datacenter that may include one or more optical interconnects according to certain embodiments;

FIG. 11 provides a block diagram of two example communication devices in communication with one another according to certain embodiments;

FIGS. 12A and 12B illustrate a top view and a perspective view, respectively, of a transceiver module operatively coupled to a network adapter, in accordance with an embodiment of the disclosure.

FIG. 13 depicts some exemplary scenarios for use of an optical transceiver, in accordance with various embodiments;

FIG. 14 provides a block diagram that schematically illustrates a computing system that may include one or more optical interconnects of various embodiments;

FIG. 15 illustrates an example computing environment, in accordance with at least one embodiment;

FIG. 16 illustrates another example computer system that may include optical interconnects, according to at least one embodiment; and

FIG. 17 is a block diagram that schematically illustrates a co-packaged Networking Device, in accordance with an embodiment that is disclosed herein.

### DETAILED DESCRIPTION

The present disclosure more fully describes various embodiments with reference to the accompanying drawings. It should be understood that some, but not all embodiments are shown and described herein. Indeed, the embodiments may take many different forms, and accordingly this disclosure should not be construed as limited to the embodiments set forth herein. Rather, these embodiments are provided so that this disclosure will satisfy applicable legal requirements. Like numbers refer to like elements throughout.

Various embodiments provide heat-managed (HM) devices, arrays of HM devices, and/or methods for fabricating HM devices (possibly arranged in an array of HM devices) where an HM device includes a semiconductor device comprising semiconductor material (e.g., a III-V semiconductor material) and a film of a thermally conductive material in direct contact with the semiconductor material. The film provides a thermal path to move heat generated via operation of the semiconductor device away from the semiconductor device (e.g., to a heat sink and/or the like). In various embodiments, the semiconductor devices are VCSELs, LEDs, DFB lasers, modulators, EMLs, photodiodes or other diodes, power transistors, and/or the like. In some embodiments, the HM devices or arrays of HM devices are part of a transceiver of an optical interconnect or other electronic device, component, or assembly.

In general, III-V semiconductor materials are poor thermal conductors. For example, GaAs has a thermal conductivity coefficient of 55 Watts per meter-Kelvin (W/m*K). Additionally, the contact between semiconductor devices formed from III-V semiconductor materials (e.g., VCSELs, short DFB lasers, LEDs, modulators, EMLs, photodiodes or other diodes, and/or the like) and the substrate the semiconductor devices are mounted to tends to be small. This results in inefficient removal of heat generated by operation of the semiconductor device. For example, the heat generated via operation of the semiconductor device may become trapped near where the heat was generated such that a hot spot is generated within the semiconductor device. As a result, the semiconductor device may become damaged and/or have unreliable operation and/or degraded performance. For example, when the semiconductor device is a VCSEL, the wavelength of the VCSEL may fluctuate or change as the temperature of the semiconductor device changes. This problem is compounded when semiconductor devices are arranged in an array where the temperature of semiconductor devices located interior to the array may have a significantly higher temperature than semiconductor devices located on edges of the array. In other words, the temperature of the semiconductor devices in the array are non-uniform. Therefore, technical problems exist regarding heat management of semiconductor devices and arrays of semiconductor devices.

Various embodiments provide technical solutions to these technical problems. For example, in various embodiments, a film of a thermally conductive material is disposed in direct contact with the semiconductor material of a semiconductor device. The film has a large thermal conductivity coefficient (e.g., greater than 400 W/m*K) in the plane of the film. The film therefore provides an efficient thermal path for transferring heat generated by operation of the semiconductor device away from the semiconductor device. For example, the film may provide a thermal path in communication with a heat sink such as a substrate, a dedicated heat sink, or an actively cooled structure (e.g., a cold finger/plate). The film therefore provides effective heat management of the semiconductor device so as to provide an HM device. Arrays of HM devices enable more consistent and/or uniform operating temperatures of the array of HM devices in time and across the array of HM devices. Various embodiments therefore provide technical improvements to the fields of semiconductor devices, arrays of semiconductor devices, fabrication of semiconductor devices, and/or the like.

Moreover, in various embodiments, the film functions as a passivation layer of the semiconductor device. For example, the film may comprise a thermally conductive, electrically non-conductive material that is applied directly to the perimeter of the semiconductor device such that the film is in direct physical contact with the semiconductor material. The film passivates the semiconductor material. Conventionally, semiconductor devices tend to be passivated using materials such as AlNₓ, SiNₓ, and SiO₂. However, these materials have poor thermal conductivity. Furthermore, passivation of these materials necessitates a plasma-enhanced chemical vapor deposition (PECVD) approach that requires a relatively high temperature process (e.g., 250-400 C). The plasma may cause damage to the surface of the semiconductor device, which may lead to increased leakage current. Additionally, at high temperatures, this process may cause poor p-type ohmic contact between metal and semiconductor surfaces, which may result in device performance impairment. Therefore, conventional passivation of semiconductor devices introduces technical problems into the fabrication of semiconductor devices.

Various embodiments provide technical improvements by using the film of thermally conductive, electrically non-conductive material to not only provide a thermal path for heat management, but to also act as a passivation layer of the semiconductor device. In certain embodiments, the application of the film to the perimeter and/or at least a portion of the (narrow) end of a mesa of the semiconductor device does not require a high temperature operation. For example, application of the film to the semiconductor device may be performed at up to 100 C. Thus, application of the film to the perimeter of the semiconductor device does not require a plasma enhanced process that may impair the device performance and enables low leakage current and good ohmic contact between the metal and semiconductor surfaces of the semiconductor device. Thus, various embodiments provide additional technical improvements and advantages to the fields of semiconductor devices, arrays of semiconductor devices, fabrication of semiconductor devices, and/or the like.

### Example Heat-Managed Devices

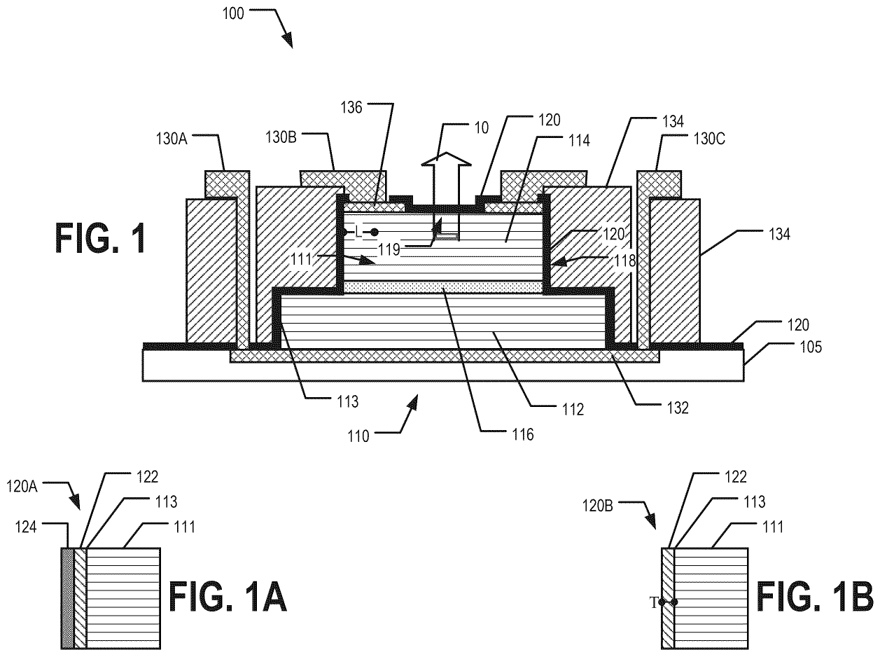

FIG. 1 provides a schematic cross-sectional diagram illustrating an example HM device 100 comprising a semiconductor device 110 and a film 120 of thermally conductive material disposed on a perimeter 113 of the semiconductor device 110. In general, the semiconductor device 110 is an electrical, optical, or electro-optical device that includes one or more semiconductor materials 111. For example, the semiconductor device 110 may include III-V semiconductor material. Some example semiconductor devices 110 include VCSELs, DFB lasers, LEDs, photodiodes or other diodes, or power transistors.

In various embodiments, the semiconductor device 110 is formed/fabricated on, disposed, or hosted by a substrate 105. In some embodiments, the substrate 105 is configured to act as a heat sink or comprises/hosts a dedicated heat sink. In some embodiments, the substrate 105 may comprise, be coupled to, and/or in thermal communication with a component configured to be actively cooled (e.g., a cold finger, cold plate, and/or the like).

The film 120 provides a thermal path for efficient transport of thermal energy from the semiconductor device 110 (e.g., from the perimeter 113 of the semiconductor device 110) to the heat sink. For example, in various embodiments, the film has an in-plane thermal conductivity coefficient of at least 400 W/m*K. In general, a film is a substantially two-dimensional material. For example, a film may be characterized by two dimensions of arbitrary scale and one dimension that is one the order of one atomic layer to 100 nm, or in certain instances, up to 300 nm. In other words, at each point on the film, a local plane is defined that has a thickness T in a range of one atomic layer to 300 nm, as shown in FIG. 1B. The thermally conductive material in some embodiments is a crystalline material. The in-plane thermal conductivity coefficient describes and/or quantifies the thermal conductivity within the (local) place defined by the substantially two-dimensional material of the film.

In some embodiments, the film 120 exhibits low thermal out-of-plane conductivity. For example, at any point on the film, a (local) plane may be defined. The out-of-plane direction is normal to the (local) plane. The thickness T of the film is measured in the out-of-plane direction. In various embodiments, the out-of-plane thermal conductivity coefficient is less than the in-plane thermal conductivity coefficient. In certain embodiments, the out-of-plane thermal conductivity coefficient is less than 100 W/m*K or possibly less than 50 W/m*K. As a result, the film 120 acts as a thermal path that efficiently transports thermal energy in an in-plane direction (e.g., to a heat sink).

In various embodiments, the film 120 is in direct physical contact and/or in close physical proximity with the perimeter 113 of the semiconductor device 110. In various embodiments, the semiconductor device 110 comprises a mesa 118 of semiconductor material. In various embodiments, the film 120 is disposed on the perimeter 113 of the mesa 118 and/or at least a portion of an (narrow) end of the mesa 119 of the semiconductor device 110. For a traditional (top-emitting) VCSEL singlet or array, this solution could help transfer heat not only through the substrate and contacts but also laterally from the mesa sidewall to the contact or substrate, in contrast to a traditional design that instead has a thermally insulating barrier. Especially for small mesa VCSELs, this could help spread the heat as the thermal resistance of the narrow diameter DBRs (e.g., second reflectors 114) are high and lateral heat spreading through and along the mesa sidewall can play a larger role in heat dissipation/management. In a dense array, where only some of the VCSELs are active, the heat could be more evenly distributed along the chip, increasing performance homogeneity and reliability. In addition, the oxidation length L of an aluminum rich content layer (e.g., of the second reflector 114) could be reduced and therefore, process could be better controlled with higher reliability compared to longer oxidation length of this oxidized layer.

In various embodiments, the film 120 is applied to the perimeter 113 of the semiconductor device 110 such that the geometry and/or topology of the semiconductor device is transferred to the film 120. For example, the geometry and/or topology of the film 120 may be that of the mesa 118. For example, the film 120 may conform to the topology of the mesa 118 of the semiconductor device 110 to provide good thermal contact between the semiconductor material 111 of the semiconductor device 110 and the film 120 of thermally conductive material.

FIG. 1A illustrates an example multi-level film 120A. A multi-level film 120A comprises a plurality of films that may each comprise a different thermally conductive material. For example, the illustrated multi-level film 120A comprises a first film 122 formed of a first thermally conductive material that is in direct physical contact with the perimeter 113 of the semiconductor device. The illustrated multi-level film 120A also includes a second film 124 that is in direct physical contact with the first film 122. In certain embodiments, the first film 122 is in direct physical contact with the semiconductor material 111 and includes a thermally conductive material that is also electrically non-conductive. For example, the first film 122 may be exposed to a P-N junction of the semiconductor device 110 (e.g., formed by first reflector 112, active region 116, and second reflector 114 in the illustrated embodiment shown in FIG. 1). In such embodiments, the first film 122 includes an electrically non-conductive material to electrically enclose and/or isolate the P-N junction. For example, the first film 122 may be a passivation layer configured to passivate the semiconductor material 111 of the semiconductor device 110. For example, the first film 122 may comprise a thermally conductive, electrically non-conductive material, such as two-dimensional hexagonal boron nitride (2D h-BN).

The 2D h-BN, is a two-dimensional material with a III-V compound containing covalently bound boron and nitrogen atoms. Since the theoretical in-plane thermal conductivity of hexagonal boron nitride can approach 750 W/m K, heat can be spread quickly laterally through a large area, avoiding formation of localized hot spots. Thin films of h-BN are characterized by high flexibility, high transmittance, high strength, high thermal conductivity, high temperature stability, and electrical insulating qualities. h-BN layers could be transferred after growth on copper/Nickel onto other substrates and could be processed by standard lithography steps to provide openings for metals, etc. Metals and other materials could be deposited on h-BN, so it could be compatible with standard semiconductor processing. The first film 122 enables to reduce hotspots and spread heat more efficiently.

The second film 124 comprises a thermally conductive material that is not in direct contact with the semiconductor material 111 (e.g., the first film 122 is disposed between the second film 124 and the semiconductor material and the first film 122 is in thermal communication with the second film 124). As the first film 122 electrically isolates the semiconductor device 110 from the second film 124, the second film 124 may include a thermally conductive material that may be electrically conductive or electrically non-conductive. For example, the second film 124 may comprise graphene. Each of the first film 122 and the second film 124 may have a respective thickness that is in a range of one atomic layer to 300 nm.

FIG. 1B illustrates an example single level film 120B. The single level film 120B consists of a first film 122 that is in direct physical contact with the perimeter 113 of the semiconductor device 110. In some embodiments, the first film is in direct physical contact with the semiconductor material 111 of the semiconductor device 110 and/or be exposed to a P-N junction of the semiconductor device 110 (e.g., formed by first reflector 112, active region 116, and second reflector 114 in the illustrated embodiment shown in FIG. 1). In such embodiments, the first film 122 includes an electrically non-conductive material to electrically enclose and/or isolate the P-N junction. For example, the first film 122 may be a passivation layer configured to passivate the semiconductor material 111 of the semiconductor device 110. For example, the first film 122 may comprise a thermally conductive, electrically non-conductive material, such as two-dimensional hexagonal boron nitride (2D h-BN). In some embodiments, the first film 122 is not in direct physical contact with the semiconductor material 11 and/or not exposed to a P-N junction of the semiconductor device 110. In such embodiments, the first film 122 may comprise an electrically conductive or an electrically non-conductive material.

The example semiconductor device 110 illustrated in FIG. 1 is a VCSEL comprising a first reflector 112 and a second reflector 114 having an active region 116 disposed between the first reflector 112 and the second reflector 114. For example, the semiconductor device 110 is formed as a mesa 118 comprising a first reflector 112, a second reflector 114, and an active region 116 positioned and/or located between the first reflector 112 and the second reflector 114. The example semiconductor device 110 also includes first electrical contacts 130A, 130C which are in electrical communication with the first reflector 112 and/or a surface of the active region 116 closest to the first reflector 112 (possibly via a current spreading layer 132). The second electrical contact 130B is in electrical communication with the second reflector 114 and/or a surface of the active region 116 that is closest to the second reflector 114 via a semiconductor contact layer 136.

When a voltage difference is applied between the electrical contacts (e.g., a voltage difference between the first electrical contacts 130A, 130C and the second electrical contact 130B), the quantum wells of the active region 116 generate light and heat. The light 10 is emitted by the VCSEL and the heat is siphoned away from the VCSEL by the film 120, in addition the substrate 105 and the contacts 130.

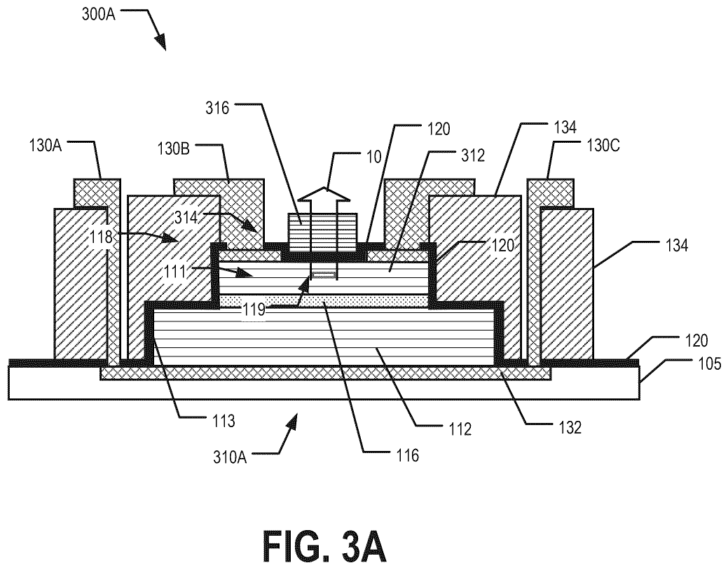

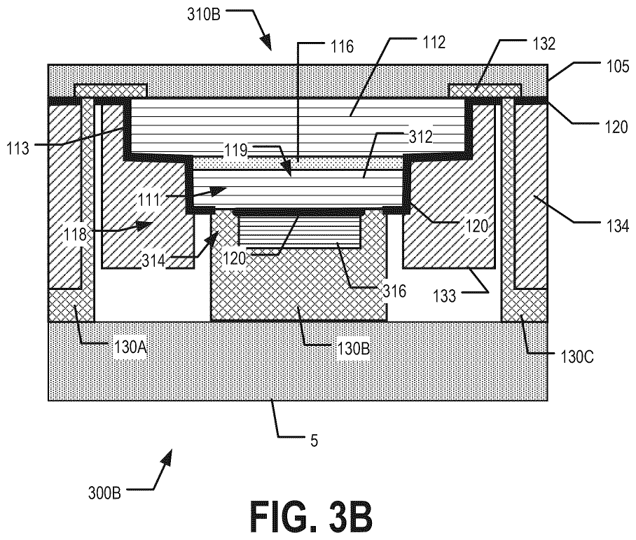

In some embodiments, the HM device 100 may further comprise one or more structural components 134. For example, the structural components 134 may be formed of Benzocyclobutene (BCB) and/or another structural material and used to provide a support structure for electrical contacts, provide structural support for flip-chip mounting of the HM device 100 (e.g., onto a second substrate 5, as shown in FIG. 3, which may or may not be configured to act as a heat sink and may be a thick dielectric layer (with relatively low refractive index) which may reduce the device capacitance for achieving higher bandwidth operation) and/or the like.

For conventional co-packaged optics (CPO), for example an array of bottom-emitting VCSELs flip-chipped onto a printed circuit board (PCB), electrical integrated circuit/driver or GPU, the heat extraction is typically be limited to the area of the metal. However, for HM devices and/or arrays of HM devices of various embodiments, the heat path can be increased to also include the insulating regions between the contacts and to divert heat from the hotter p-side to the larger area n-side contacts.

For infrared (IR) wavelength (relevant for telecommunication) signals/beams, the h-BN is transparent. This enables the h-BN (e.g., in the form of first film 122) to be used in the center (hottest part) of the mesa where it could be used as a thermally conductive transparent layer for lateral/vertical heat transport. In some embodiments, the film 120 (e.g., especially when the film comprises a first film comprising h-BN) may be used to tune the reflectivity of the second reflector 114 to replace a traditional thermally isolating passivation AR-coating or mode filter dielectric layer.

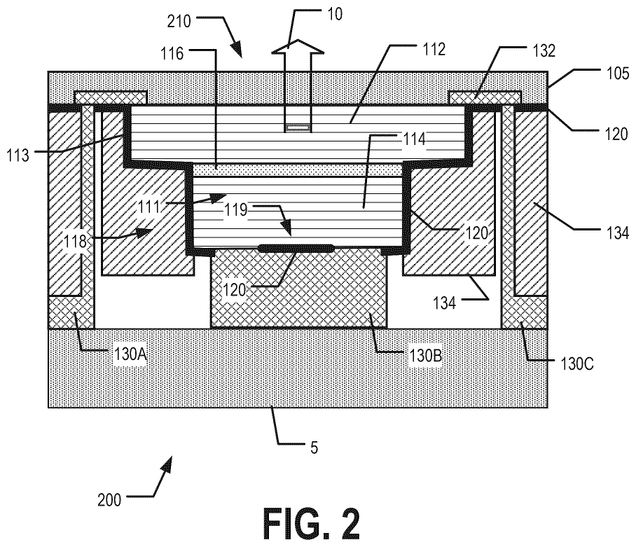

FIG. 2 provides a schematic cross-sectional view of an example flip-chip mounted HM device 200. The flip-chip HM device 200 is formed on a first substrate 105 and flip-chip mounted onto a second substrate 5. For example, the contacts 130 (e.g., 130A, 130B, 130C) of the HM device 200 are mechanically secured into electrical communication with bond pads, for example, hosted by the second substrate 5. The flip-chip HM device 200 comprises a flip-chip semiconductor device 210 having a film 120 comprising thermally conductive material in direct physical contact with the semiconductor material 111 of the flip-chip semiconductor device 210. For example, the film 120 is disposed on the perimeter of the mesa 118 of the flip-chip semiconductor device 210 and at least a portion of the (narrow) end of the mesa 119 of the flip-chip semiconductor device 210 (e.g., a VCSEL in the illustrated embodiment). This causes the film to be placed as close as possible to the heat source of the flip-chip mounted semiconductor device 210 such that the heat may be efficiently transported away from the semiconductor device(s) via the thermal path provided by the film 120.

FIGS. 3A and 3B illustrate two example HM devices 300A, 300B where the second reflector 313 is configured to enable the film 120 of thermally conductive material located at the (narrow) end of the mesa 119 to be disposed within the second reflector 314. For example, the HM devices 300A, 300B include semiconductor devices 310A, 310B where the second reflector includes a semiconductor-based DBR portion 312 and a dielectric-based DBR portion 316. The film 120 of thermally conductive material is disposed between the semiconductor-based DBR portion 312 and the dielectric-based DBR portion 316. This enables the film 120 to be located in closer proximity to the location within the semiconductor device 310A, 310B where the heat is generated (e.g., within the active region 116) compared to the semiconductor devices 110, 310. For example, the semiconductor-based DBR portion 312 may be thinner and/or include fewer layers than the second reflector 114, 314 (which consists of semiconductor materials 111). The dielectric-based DBR portion 316 is configured such that that the total reflectivity of the second reflector 314 is a desired reflectivity (e.g., possibly a reflectivity similar that of the second reflectors 114, 314).

### Example Array of HM Devices

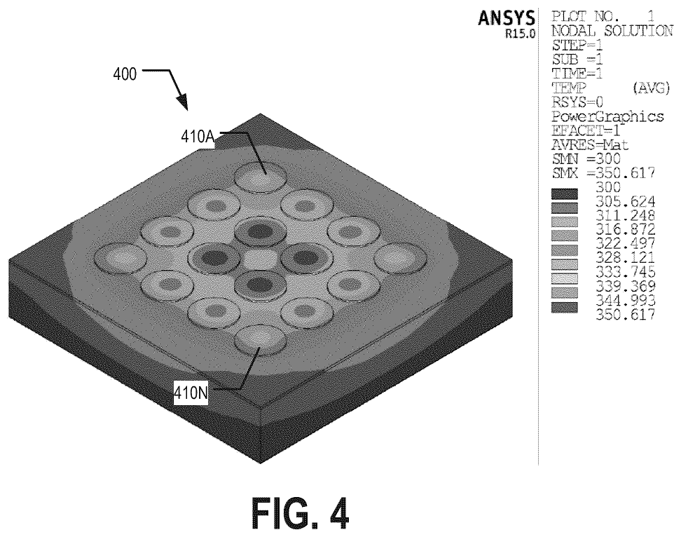

FIG. 4 illustrates the temperature distribution of an array 400 of conventional semiconductor devices (VCSELs in this simulation) 410A-410N, as reported by Jin et al. in “Thermal Design of VCSEL Arrays for Optical Output Power Improvement.” As shown in FIG. 4, the temperature of the semiconductor devices in the middle of the array is significantly higher than the temperature of the semiconductor devices along the edges of the array. Moreover, the semiconductor devices on the outside corners of the array have a temperature that is less than the temperature of the other semiconductor devices along the edges of array and significantly less than the temperature of the semiconductor devices in the middle of the array. This temperature differential across the array of semiconductor devices affects the overall performance and reliability of the array of semiconductor devices.

In various embodiments, an array of HM devices are provided. The array of HM devices comprises a plurality of HM devices where each HM device comprises a respective semiconductor device that has a film comprising a thermally conductive material applied to the perimeter of the semiconductor device. The film of thermally conductive material is configured to place the semiconductor device in thermal communication with a heat sink and/or to provide a thermal path for efficient transfer of thermal energy from the semiconductor to a heat sink, for example. In various embodiments, the film of thermally conductive material is configured to cause an even or (substantially) uniform distribution of heat across the array of HM devices.

In various embodiments, a film (single level or multi-level) is in direct physical contact with the semiconductor material of the semiconductor devices of an array of HM devices. This enables the efficient transport of heat away from the array of semiconductor devices (e.g., to a heat sink) and also causes the heat to be more evenly distributed along the chip, increasing performance homogeneity and reliability. For example, the film of thermally conductive material causes the temperature of the semiconductor devises of the array of HM devices to be more consistent and/or uniform.

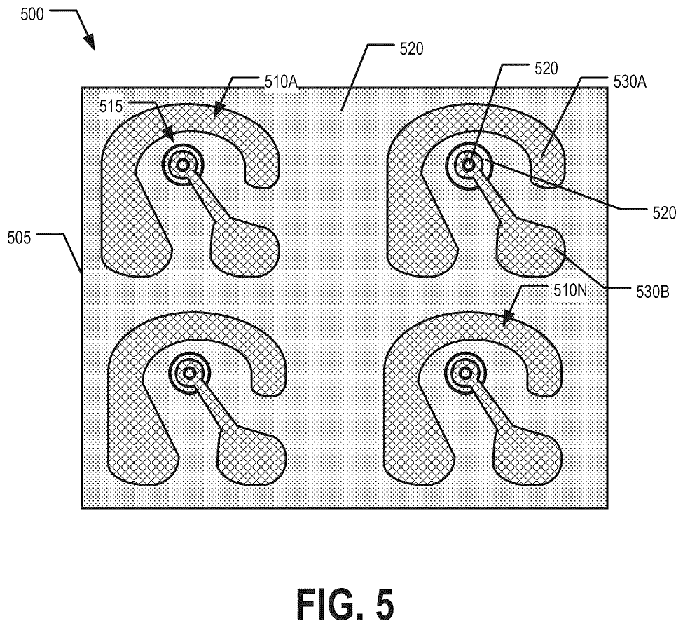

FIG. 5 illustrates an example array of HM devices 500 formed and/or disposed on a substrate 505. The array of HM devices 500 comprises a plurality of HM devices 510A-510N. Each of the HM devices 510A-510N comprises a respective semiconductor device 515. For example, the semiconductor devices 515 may be semiconductor devices 110, 210, 310A, 310B or other semiconductor devices. For example, the semiconductor devices 515 may be VCSELs, LEDs, photodiodes, and/or the like. Various embodiments may also provide arrays of DFB lasers, EMLs, modulators, various diodes, power transistors, and/or the like. The semiconductor devices 515 each include semiconductor material (e.g., III-V semiconductor material) and electrical contacts 530A, 530B for applying voltage and/or electrical signals to the semiconductor material so as to cause operation of the semiconductor devices.

A film 520 (e.g., a multi-level film or signal level film) is disposed on the respective perimeters of the semiconductor devices 515 and/or at least a portion of the end of the mesas of the semiconductor devices 515. The film 520 comprises a thermally conductive material such as 2D h-BN, graphene, AlN, and/or the like. In certain embodiments, the film 520 comprises a thermally conductive, electrically non-conductive material, such as 2D h-BN. In various embodiments, the film 520 has an in-plane thermal conductivity coefficient of at least 400 W/m*K.

In various embodiments, the semiconductor devices 515 are in thermal communication with a heat sink via the film 520. For example, the film 520 may provide thermal paths for efficient transport of thermal energy generated via operation of the semiconductor devices 515 to the substrate or another heat sink. In certain embodiments, in addition to being disposed on the perimeter and (narrow) end of the mesas of the semiconductor devices 515, the film 520 may also be disposed along (and possibly in thermal communication with) at least a portion of the substrate 505 to provide and/or define a thermal path away from the semiconductor devices 515 and to a heat sink, for example. The structural components 134 formed of Benzocyclobutene (BCB) and/or another structural material are omitted from FIG. 5 to illustrate the film 520 disposed across the substrate 505.

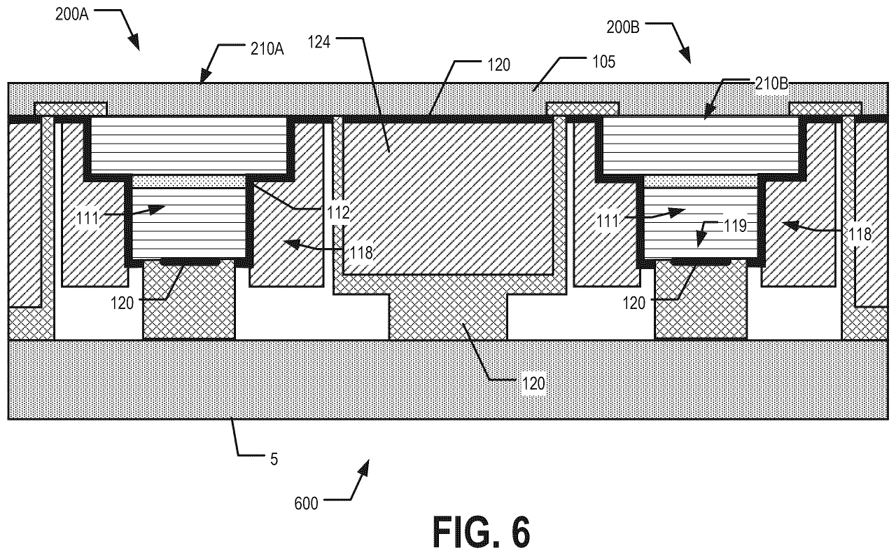

FIG. 6 illustrates a cross-sectional view of a portion of an array 600 of flip-chip mounted HM devices 200 (e.g., 200A, 200B). As shown in FIG. 6, the film 120 may be disposed on the perimeters 113 of the mesas of the semiconductor devices 210A, 210B, at the (narrow) end of the mesas 119 of the semiconductor devices 210 (e.g., 210A, 210B), and/or along the surface of the substrate 105. This enables efficient transport of heat away from the semiconductor devices 210 and/or efficient spreading of the heat such that the heat distribution across the array 600 is substantially uniform.

### Example Method for Fabricating an HM Device

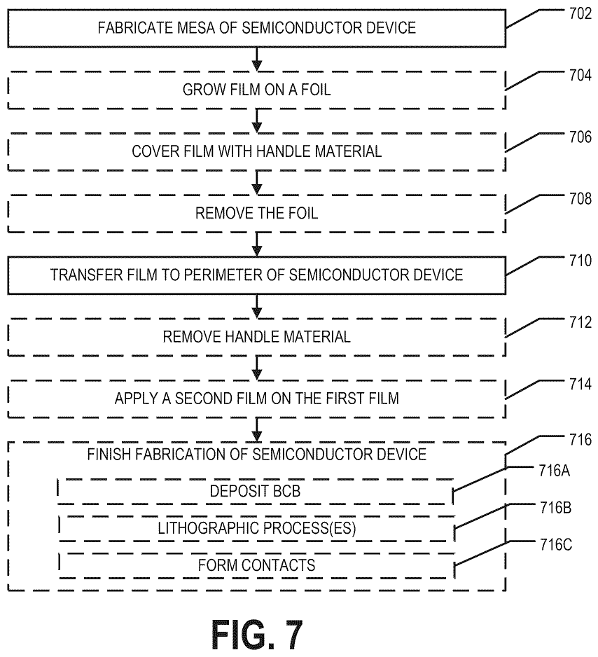

FIG. 7 provides a flowchart illustrating various processes, procedures, operations, and/or the like for fabricating an HM device comprising a semiconductor device having a film comprising a thermally conductive material applied to and/or disposed on a perimeter of the semiconductor device.

Starting at step 702, one or more semiconductor components of a semiconductor device are fabricated. For example, a semiconductor device includes one or more structures formed of semiconductor material. In the example HM devices 100, 200, 300A, 300B illustrated in FIGS. 1, 2, 3A, and 3B these structures formed of semiconductor material include the first reflector 112, the active region 116, and the second reflector 114 (or at least the semiconductor-based portion 312 of the second reflector 314). For example, the mesa 118, 218 of the semiconductor device 110, 310A, 310B may be fabricated. Fabricating the semiconductor components of the semiconductor device may include epitaxially growing and/or depositing one or more layers (of semiconductor material), bonding epitaxial layers grown on different substrates, etching various layers to form and/or define a mesa of the semiconductor device, and/or the like.

At step 704, a film comprising a thermally conductive material is grown on a foil or substrate. For example, in certain embodiments, the film comprises 2D h-BN that is grown on a copper foil, for example, at a temperature of about 1000° C.

At step 706, the film is covered with a handle material. For example, the handle material may be poly(methyl methacrylate) (PMMA) or another material configured to provide structural support and handleability of the film.

At step 708, the foil or other substrate that the film was grown on is removed. For example, one or more wet or dry etching techniques may be used to remove the foil or other substrate.

At step 710, the film is applied and/or transferred to the perimeter of the semiconductor device. For example, the film may be applied to and/or transferred to the perimeter of the semiconductor device such that a geometry and/or topology of the semiconductor device is transferred to the film. For example, the topology of the film may be defined by the topology of a mesa of the semiconductor device.

At step 712, the handle material is removed. For example, a wet or dry etching process may be performed to remove the handle material (e.g., PMMA).

In some embodiments, the film is a multi-level film comprising a plurality of films (e.g., at least a first film and a second film). In some embodiments, step 704 includes growing the multi-level film and the entire multi-level film is applied to and/or transferred to the perimeter of the semiconductor device at step 710. In some embodiments, the film is a multi-level film that is applied and/or transferred onto the semiconductor device iteratively. For example, at step 714, a second film may be applied onto the first film. For example, the film applied and/or transferred to the perimeter of the semiconductor device at step 710 may be a first film. In some embodiments, the first film comprises a thermally conductive material that is electrically non-conductive. For example, the first film may be applied and/or transferred to the perimeter of the semiconductor device to form a thermally conductive passivation layer. A second film may then be applied and/or transferred onto the first film. The second film comprises thermally conductive material that may be the same or different from the thermally conductive material of the first film. For example, the first film may include a thermally conductive, electrically non-conductive material and the second film may include a thermally conductive, electrically conductive material, for example.

At step 716, the fabrication of the semiconductor device is finished or completed. For example, BCB or another structural material may be deposited to form structure components of the semiconductor device at step 716A. At step 716B, one or more lithographic processes may be performed to form openings (e.g., through the BCB, film, and/or the like) to enable formation of electrical contacts and/or the like. At step 716C, on or more electrical contacts may be deposited and/or patterned such that appropriate portions of the HM device may be placed into electrical communication with electrical signals configured for operating the HM device. In certain embodiments, a dielectric DBR is fabricated on the film 120 of thermally conductive material disposed at the (narrow) end of the mesa 119, as shown in FIGS. 3A and 3B, as part of step 716.

While FIG. 7 describes the fabrication of a single HM device 100, 200 one of ordinary skill in the art should understand that an array of HM devices 500, 600 may be fabricated by performing the steps of FIG. 7 on the HM devices of the array of HM devices in parallel, for example.

In some embodiments, the film comprises aluminum nitride (AlN) or another thermally conductive material that may be deposited via atomic layer deposition (ALD). For example, AlN may be deposited on the perimeter and/or (narrow) end of the mesa of the semiconductor device using ALD at a temperature of around 100 C. For example, steps 704-712 may be replaced with an ALD step in some embodiments. While the AlN is deposited as a three-dimensional crystal, the total deposition is generally thin (e.g., in a range of one atomic layer to 100 nm) such that the material is substantially 2D.

### Example Optical Interconnect Including a Device or Array of Devices

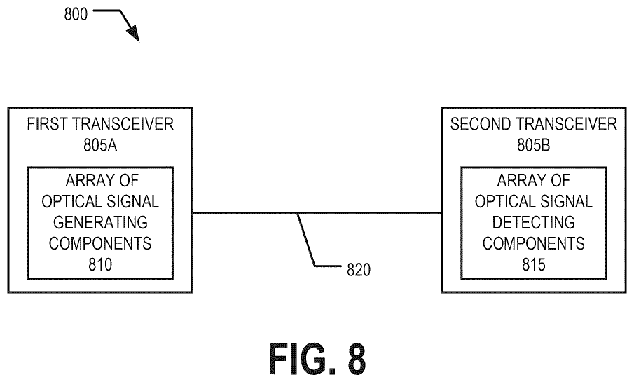

FIG. 8 illustrates an example optical interconnect 800 including one or more HM devices or arrays of HM devices of various embodiments. As should be understood, HM devices and/or arrays of HM device of various embodiments may be incorporated into a variety of components, assemblies, and/or systems. Optical interconnects including one or more HM devices or arrays of HM devices of various embodiments are illustrated herein to provide an example of on such component, assembly, and/or system in which HM devices or arrays of HM devices of various embodiments may be incorporated.

The optical interconnect 800 comprises a first transceiver 805A and a second transceiver 805B. The first transceiver 805A is in optical communication with the second transceiver 805B via one or more optical fibers 820. The first transceiver 805A comprises an array of optical signal generating components 810. In various embodiments, the array of optical signal generating components 810 is an array of HM devices of an example embodiment. For example, the array of optical signal generating components 810 comprises an array of VCSELs, DFB lasers, LEDs, and/or other optical signal generating devices that each include a semiconductor device having a film comprising a thermally conductive material applied to and/or disposed on the perimeter of the semiconductor device. As shown in FIG. 5, in conventional VCSELs arrays, the temperature difference between inner and outer VCSELs can be significant, affecting overall performance and reliability.

The second transceiver 805B comprises an array of optical signal detecting components 815. In various embodiments, the array of optical signal detecting components 815 is an array of HM devices of an example embodiment. For example, the array of optical signal detecting components 815 comprises an array of photodiodes and/or other optical signal detecting devices that each include a semiconductor device having a film comprising a thermally conductive material applied to and/or disposed on the perimeter of the semiconductor device.

For example, the first transceiver 805A comprises one or more optical signal generating components that may include respective semiconductor devices having a film comprising thermally conductive material disposed on respective perimeters of the semiconductor material of the respective semiconductor devices. The one or more optical signal generating components generate one or more optical signals that are then provided to the second transceiver 805B via the optical fiber 820, for example. One or more optical signal detecting components that may include respective semiconductor devices having a film comprising thermally conductive material disposed on respective perimeters of the semiconductor material of the respective semiconductor devices may receive and/or detect the one or more optical signals such that information is communicated from the first transceiver 805A to the second transceiver 805B via the optical signal(s).

### Example Datacenter

In various embodiments, a system includes an HM device comprising a semiconductor device having a film of thermally conductive material applied to and/or disposed on a perimeter of the semiconductor material of the semiconductor device. In some embodiments a system includes an array of HM devices where the HM devices comprise semiconductor devices having a film of thermally conductive material applied to and/or disposed on respective perimeters of the semiconductor material of the semiconductor devices. For example, as shown in FIG. 8, an HM device or an array of HM devices of various embodiments may be incorporated into an optical interconnect. Such an optical interconnect may be part of a datacenter.

For example, an optical interconnect comprising one or more HM devices or arrays of HM devices of various embodiments may be used to place various components of a datacenter in communication with one another. In various embodiments, the system may include a pluggable optical interconnect, a chip-to-chip optical interconnect, an optical network comprising a plurality of optical interconnect, and/or the like that include one or more HM devices and/or one or more arrays of HM devices of various embodiments. For example, one or more HM devices 100, 300 may be VCSELs, DFB lasers, LEDs (e.g. micro-LEDs) and/or the like configured to generate optical signals and may be used to generate optical signals that are transmitted along one or more optical communication paths between two components of a datacenter, in accordance with an example embodiment.

Datacenters may include multiple network switches in a particular topology, such as a fat tree topology, a slim fly topology, a dragonfly topology, and/or the like. The specifications and makeup of the network switches in the topology affects the overall network performance (e.g., bandwidth capability) of the datacenter.

Datacenters are the storage and data processing hubs of the internet. The massive deployment of cloud applications is causing datacenters to expand exponentially in size, stimulating the development of faster switches than can cope with the increasing data traffic inside the datacenter. Current state-of-the-art switches are capable of handling 12.8 Tb/s of traffic by employing electrical switches in the form of application specific integrated circuits (ASICs) equipped with 256 data lanes, each operating at 50 Gbps. Such switching ASICs typically consume as much as 400 W, and the power consumption of the optical transceiver interfaces attached to each ASIC is comparable. To keep pace with traffic demand, switch capacity doubles approximately every two years. To date, this rapid scaling has been made possible by exploiting advances in manufacturing (e.g., CMOS techniques), collectively described by Moore's law (i.e., the observation that the number of transistors in a dense integrated circuit doubles about every two years). However, in recent years there are strong indications of Moore's law slowing down, which raises concerns about the capability to sustain the target scaling rate of switch capacity. As a result, alternative technologies are being investigated.

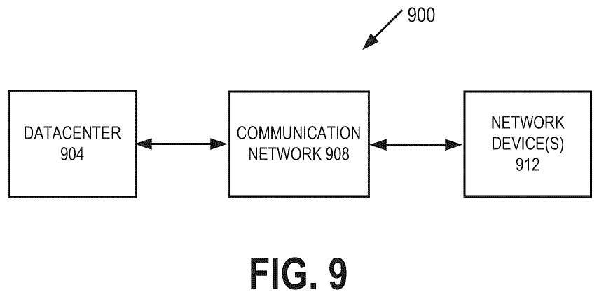

FIG. 9 illustrates a system 900 according to at least one example embodiment. The system 900 includes a datacenter 904, a communication network 908, and one or more network devices 912. In at least one example embodiment, the datacenter 904 corresponds to a collection of network devices, such as network switches (e.g., Ethernet switches) connected with a collection of servers or compute nodes. The datacenter 904 may adhere to a networking topology (e.g., a hierarchal networking topology), such as a fat tree topology, a Slim Fly topology, a Dragonfly topology, and/or the like. The datacenter 904 routes traffic amongst the network switches and servers therein, and at least one layer of the topology in the datacenter 904 is coupled to the communication network 908 to allow networking traffic to flow between the datacenter 904 and the network device(s) 912.

Examples of the communication network 908 that may be used to connect the datacenter 904 and the network device(s) 912 include an Internet Protocol (IP) network, an Ethernet network, an InfiniBand (TB) network, a Fibre Channel network, the Internet, a cellular communication network, a wireless communication network, combinations thereof (e.g., Fibre Channel over Ethernet), variants thereof, and/or the like.

The one or more network devices 912 may include switch, router, or Network Interface Controller (NIC), interconnect using ports, one or more of Personal Computer (PC), a laptop, a tablet, a smartphone, a server, a collection of servers, and/or any suitable computing device for sending and receiving signals over the communication network 908. In at least one example embodiment, the one or more network devices 912 correspond to another datacenter, similar to or the same as datacenter 904.

As noted above, the datacenter 904 and/or the network device(s) 912 may include storage devices and/or processing circuitry for carrying out computing tasks, for example, tasks associated with controlling the flow of data internally and/or over the communication network 908. Such processing circuitry may comprise software, hardware, or a combination thereof. For example, the processing circuitry may include a memory including executable instructions and a processor (e.g., a microprocessor) that executes the instructions on the memory. The memory may correspond to any suitable type of memory device or collection of memory devices configured to store instructions. Non-limiting examples of suitable memory devices that may be used include Flash memory, Random Access Memory (RAM), Read Only Memory (ROM), variants thereof, combinations thereof, or the like. In some embodiments, the memory and processor may be integrated into a common device (e.g., a microprocessor may include integrated memory).

Additionally or alternatively, the processing circuitry may comprise hardware, such as an application specific integrated circuit (ASIC). For example, the processor may be or include one or more of an Integrated Circuit (IC) chip, a microprocessor, a Central Processing Unit (CPU), a Graphics Processing Unit (GPU), a Data Processing Unit (DPU), a Field Programmable Gate Array (FPGA), a network interface controller (NIC), an ASIC, combinations thereof, and the like. The processing circuitry may comprise an ASIC and/or may be capable of performing as a central processing unit (CPU), a graphics processing unit (GPU), a network interface controller (NIC), a data processing unit (DPU), or any other computing device in which with data is received and/or transmitted.

Some or all of the processing circuitry may be provided on a Printed Circuit Board (PCB) or collection of PCBs. It should be appreciated that any appropriate type of electrical component or collection of electrical components may be suitable for inclusion in the processing circuitry.

In addition, although not explicitly shown, it should be appreciated that the datacenter 904 and network device(s) 912 may include one or more communication interfaces for facilitating wired and/or wireless communication between one another and other unillustrated elements of the system 900.

In related art systems, a fat tree topology may use the same electrical switching devices on all layers (edge, aggregation, core). For example, each switching device may be 1 U switch, where 1 U refers to the industry standard size for rack-mounted switch and/or server. The interconnection between switches of different layers may be accomplished with optical links or optical interconnects using active optical cables and optical transceivers implemented in a pluggable form factor (also referred to as “pluggables”).

Optical Datacenter Networks rely on allocation and deallocation of light paths from the data sources to the destinations end-ports to guarantee no light collisions and data loss occur in the fabric. Traditionally the allocation algorithms are run from a central entity which considers the entire demand for source and destination flows and try to find the most dense mapping of these demands to network resources over a single or multiple time periods.

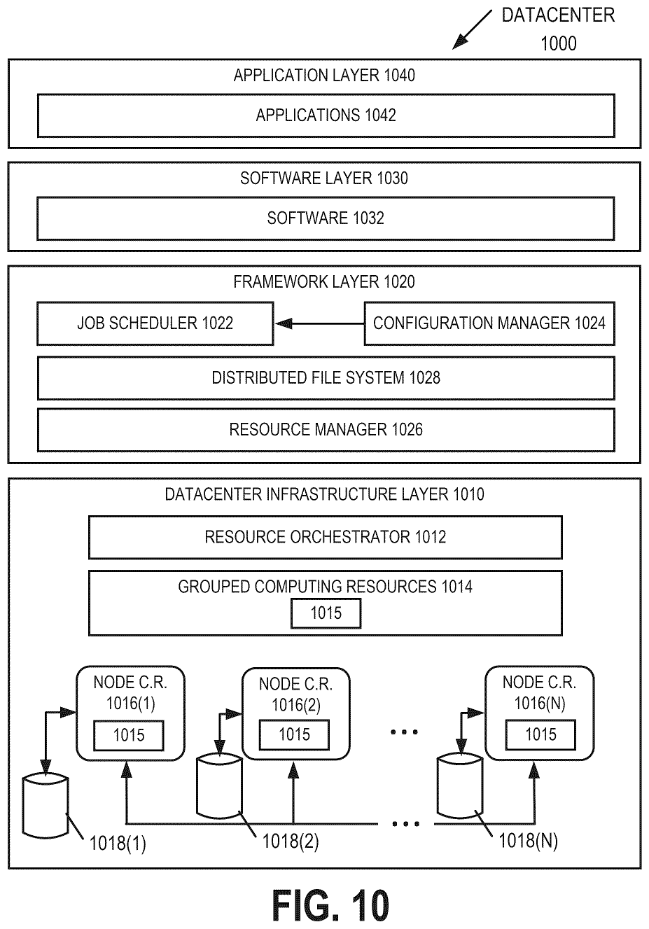

FIG. 10 illustrates an example datacenter 1000, in which at least one embodiment may be used. In at least one embodiment, datacenter 1000 includes a datacenter infrastructure layer 1010, a framework layer 1020, a software layer 1030, and an application layer 1040.

In at least one embodiment, as shown in FIG. 10, datacenter infrastructure layer 1010 may include a resource orchestrator 1012, grouped computing resources 1014, and node computing resources (“node C.R.s”) 1016(1)-1016(N), where “N” represents a positive integer (which may be a different integer “N” than used in other figures). In at least one embodiment, node C.R.s 1016(1)-1016(N) may include, but are not limited to, any number of central processing units (“CPUs”) or other processors (including accelerators, field programmable gate arrays (FPGAs), graphics processors, etc.), memory storage devices 1018(1)-1018(N) (e.g., dynamic read-only memory, solid state storage or disk drives), network input/output (“NW I/O”) devices, network switches, virtual machines (“VMs”), power modules, and cooling modules, etc. In at least one embodiment, one or more node C.R.s from among node C.R.s 1016(1)-1016(N) may be a server having one or more of above-mentioned computing resources.

In at least one embodiment, grouped computing resources 1014 may include separate groupings of node C.R.s housed within one or more racks (not shown), or many racks housed in datacenters at various geographical locations (also not shown). In at least one embodiment, separate groupings of node C.R.s within grouped computing resources 1014 may include grouped compute, network, memory, or storage resources that may be configured or allocated to support one or more workloads. In at least one embodiment, several node C.R.s including CPUs or processors may grouped within one or more racks to provide compute resources to support one or more workloads. In at least one embodiment, one or more racks may also include any number of power modules, cooling modules, and network switches, in any combination.

In at least one embodiment, resource orchestrator 1012 may configure or otherwise control one or more node C.R.s 1016(1)-1016(N) and/or grouped computing resources 1014. In at least one embodiment, resource orchestrator 1012 may include a software design infrastructure (“SDI”) management entity for datacenter 1000. In at least one embodiment, resource orchestrator 1012 may include hardware, software or some combination thereof.

In at least one embodiment, as shown in FIG. 10, framework layer 1020 includes a job scheduler 1022, a configuration manager 1024, a resource manager 1026 and a distributed file system 1028. In at least one embodiment, framework layer 1020 may include a framework to support software 1032 of software layer 1030 and/or one or more application(s) 1042 of application layer 1040. In at least one embodiment, software 1032 or application(s) 1042 may respectively include web-based service software or applications, such as those provided by Amazon Web Services, Google Cloud and Microsoft Azure. In at least one embodiment, framework layer 1020 may be, but is not limited to, a type of free and open-source software web application framework such as Apache Spark™ (hereinafter “Spark”) that may utilize distributed file system 1028 for large-scale data processing (e.g., “big data”). In at least one embodiment, job scheduler 1022 may include a Spark driver to facilitate scheduling of workloads supported by various layers of datacenter 1000. In at least one embodiment, configuration manager 1024 may be capable of configuring different layers such as software layer 1030 and framework layer 1020 including Spark and distributed file system 1028 for supporting large-scale data processing. In at least one embodiment, resource manager 1026 may be capable of managing clustered or grouped computing resources mapped to or allocated for support of distributed file system 1028 and job scheduler 1022. In at least one embodiment, clustered or grouped computing resources may include grouped computing resources 1014 at datacenter infrastructure layer 1010. In at least one embodiment, resource manager 1026 may coordinate with resource orchestrator 1012 to manage these mapped or allocated computing resources.

In at least one embodiment, software 1032 included in software layer 1030 may include software used by at least portions of node C.R.s 1016(1)-1016(N), grouped computing resources 1014, and/or distributed file system 1028 of framework layer 1020. In at least one embodiment, one or more types of software may include, but are not limited to, Internet web page search software, e-mail virus scan software, database software, and streaming video content software.

In at least one embodiment, application(s) 1042 included in application layer 1040 may include one or more types of applications used by at least portions of node C.R.s 1016(1)-1016(N), grouped computing resources 1014, and/or distributed file system 1028 of framework layer 1020. In at least one embodiment, one or more types of applications may include, but are not limited to, any number of a genomics application, a cognitive compute, application and a machine learning application, including training or inferencing software, machine learning framework software (e.g., PyTorch, TensorFlow, Caffe, etc.) or other machine learning applications used in conjunction with one or more embodiments.

In at least one embodiment, any of configuration manager 1024, resource manager 1026, and resource orchestrator 1012 may implement any number and type of self-modifying actions based on any amount and type of data acquired in any technically feasible fashion. In at least one embodiment, self-modifying actions may relieve a datacenter operator of datacenter 1000 from making possibly bad configuration decisions and possibly avoiding underutilized and/or poor performing portions of a datacenter.

In at least one embodiment, datacenter 1000 may include tools, services, software, or other resources to train one or more machine learning models or predict or infer information using one or more machine learning models according to one or more embodiments described herein. For example, in at least one embodiment, a machine learning model may be trained by calculating weight parameters according to a neural network architecture using software and computing resources described above with respect to datacenter 1000. In at least one embodiment, trained machine learning models corresponding to one or more neural networks may be used to infer or predict information using resources described above with respect to datacenter 1000 by using weight parameters calculated through one or more training techniques described herein.

In at least one embodiment, datacenter may use CPUs, application-specific integrated circuits (ASICs), GPUs, FPGAs, or other hardware to perform training and/or inferencing using above-described resources. Moreover, one or more software and/or hardware resources described above may be configured as a service to allow users to train or performing inferencing of information, such as image recognition, speech recognition, or other artificial intelligence services.

Inference and/or training logic 1015 are used to perform inferencing and/or training operations associated with one or more embodiments. In at least one embodiment, inference, and/or training logic 1015 may be used in system FIG. 10 for inferencing or predicting operations based, at least in part, on weight parameters calculated using neural network training operations, neural network functions and/or architectures, or neural network use cases described herein.

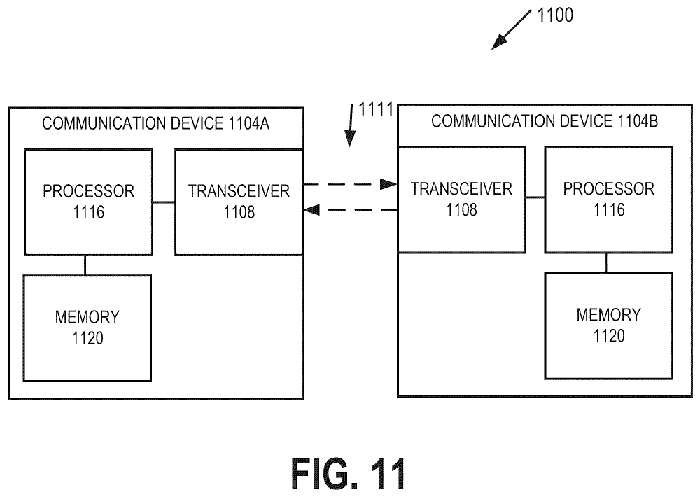

FIG. 11 illustrates a system 1100 including a first communication device 1104A and a second communication device 1104B. Illustratively, but without limitation, the communication devices 1104 (e.g., 1104A, 1104B) may correspond to network devices (e.g., network devices 911). As such, the communication devices 1104 may correspond to any type of device that becomes part of or is connected with a communication network (e.g., communication network 808). Examples of suitable devices that may act or operate like a communication device 1104 as described herein include, without limitation, one or more of a Personal Computer (PC), a laptop, a tablet, a smartphone, a server, a collection of servers, a networking card, an edge router, a switch, Network Interface Controller, a Top of Rack (ToR) switch, a server blade, or the like. The communication device 1104 may include a transceiver 1108, a processor 1116, and memory 1120. The transceiver 1108 may include hardware that enables communications over the communication channel 1111 whereas the processor 1116 and memory 1120 may include components that enable the communication device 1104 to provide a desired functionality or perform certain functions.

The communication channel 1111 may traverse a datacenter or any type of communication network (whether trusted or untrusted). Examples of a communication network that may be used to connect communication devices 1104 and support the communication channel 1111 include, without limitation, an Internet Protocol (IP) network, an Ethernet network, an InfiniBand (IB) network, a Fibre Channel network, the Internet, a cellular communication network, a wireless communication network, combinations thereof (e.g., Fibre Channel over Ethernet), variants thereof, and/or the like. In one specific, but non-limiting example, the communication network enables data transmission between the communication devices 1104 using optical signals. In this case, the communication devices 1104 and the communication network may include waveguides (e.g., optical fibers) that carry the optical signals. For example, the communication devices and/or the communication network may include one or more HM devices 100, 300 and/or arrays of HM devices 500, 600, according to various embodiments.

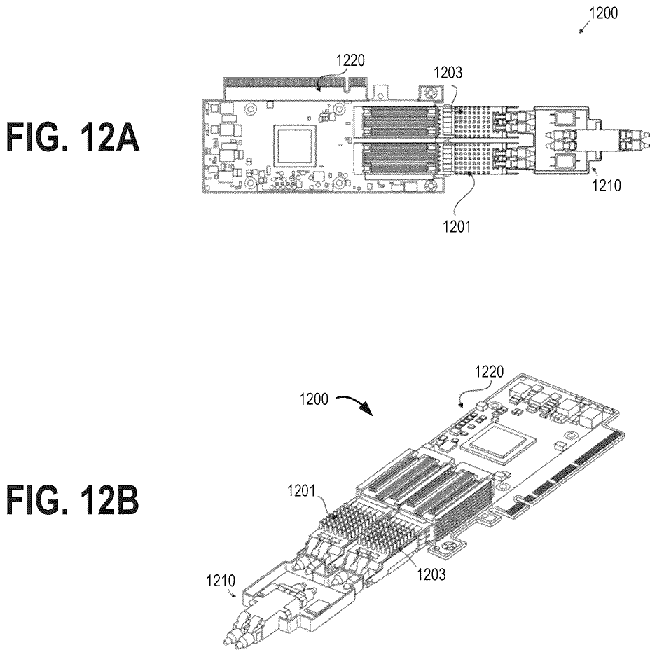

FIGS. 12A and 12B illustrate a top view and a perspective view, respectively, of a transceiver module operatively coupled to a network adapter, in the present example a Network Interface Controller (NIC) 1200, in accordance with an embodiment of the disclosure. As shown in FIGS. 12A and 12B, the transceiver module may include a first optical module 1201, a second optical module 1203, an adapter 1210, and a dual-port NIC 1220 of a server. Both the first optical module 1201 and the second optical module 1203 may be dual-fiber transceivers that are configured for duplex communication that allows the source (e.g., server) to communicate with the target (e.g., leaf switch) in both directions. The adapter 1210 may be a ganged physical component configured to link the first optical module 1201 and the second optical module 1203 for the purpose of transmitting and receiving data to and from the leaf switch.

In some embodiments, the adapter 1210 may be configured to operate in two configurations, such as a first configuration and a second configuration. In one aspect, the first configuration may be a default configuration of operation, where the first optical module 1201 may be operationally active. The second configuration may be a contingent configuration that is implemented when the first optical module 1201 operationally fails. When such a failure is detected, the second optical module 1203, which is otherwise operationally inactive or idle, may be engaged become operationally active and handle all network traffic that was initially handled by the first optical module 1201.

In some embodiments, the transceiver module 1200 may be configured to operate in a leaf-spine architecture. A leaf-spine architecture is a data center network topology that may include two switching layers—a spine layer and a leaf layer. The leaf layer may include access switches (leaf switches) that aggregate traffic from servers and connect directly into the spine or network core. Spine switches interconnect all leaf switches in a full-mesh topology between access switches in the leaf layer and the servers from which the access switches aggregate traffic. As such, in one embodiment, to ensure reliable operation of downlinks, the transceiver module 1200 may be configured to operate between the server and the leaf layer. In particular, as shown in FIGS. 12A and 12B, the adapter 1210 may be operatively coupled to the first optical module 1201 and the second optical module 1203, while the first optical module 1201 and the second optical module 903 may be operatively coupled to a dual-port NIC 1220 of a server.

In embodiments, NIC 1200 may comprise one or more processing circuits, as detailed above; the processing circuits may comprise FW, that is loaded according to the techniques described above.

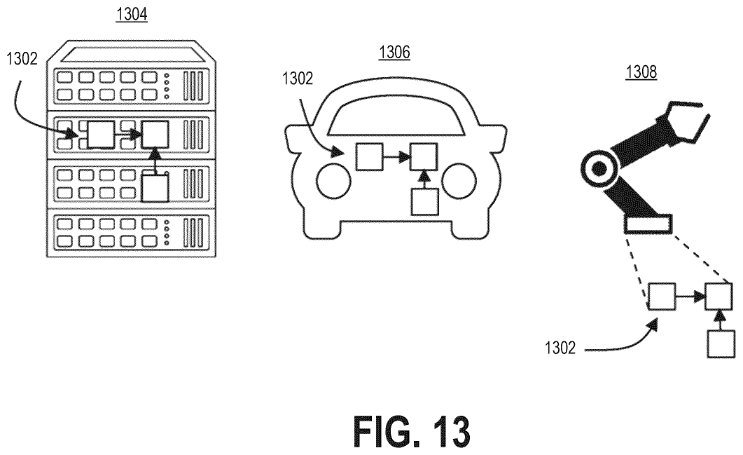

FIG. 13 depicts some exemplary scenarios for use of an optical transceiver 1302 in accordance with some embodiments. An optical transceiver 1302 may be utilized in a computing system 1304 (e.g., in a server farm, or within a server computer system), a vehicle 1306 (e.g., a car, truck, train, or airplane), and a robot 1308 (or among robots in a factory), to name just a few examples. The optical transceiver 1302 may be particularly useful for high-speed communication in environments subject to high levels of electromagnetic interference (EMI).

### Example System Use Case

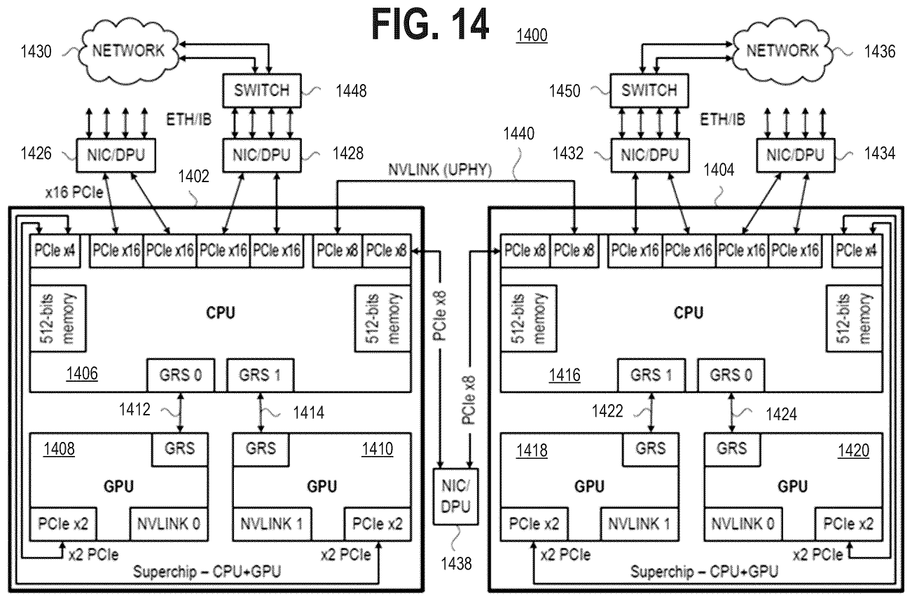

FIG. 14 is a block diagram that schematically illustrates a computing system 1400, e.g., a data center or a High-Performance Computing (HPC) cluster, in accordance with an embodiment that is described herein. System 1400 comprises a plurality of subsystems, e.g., multiple processing devices coupled to each other, multiple network devices, and multiple networks, according to at least one embodiment. Computing system 1400 is designed with multiple integrated circuits (referred to as processing devices), where each integrated circuit can include one or more CPUs and GPUs, forming a powerful and flexible architecture.

The various processing devices are interconnected via an NVLink or other high-speed interconnect, enabling high-speed communication between the subsystems, and are also connected through a NIC or DPU to ensure efficient data transfer across computing system 1400 and to one or more external networks 1430, 1436. In the present example, system 1400 comprises a packet switch 1448 that connects NIC/DPU 1428 to network 1430, and a packet switch 1450 that connects NIC/DPU 1432 to network 1436.

The coupling of processing devices through NVLink allows for seamless data exchange and parallel processing, enhancing overall computational performance. The processing devices are connected to multiple networks through one or more network interface controllers (NICs) or DPUs, enabling the system to handle complex, multi-network tasks with high bandwidth and low latency. This configuration is highly suitable for demanding applications that require significant processing power, such as artificial intelligence (AI), machine learning (ML), and data-intensive computing, while ensuring robust connectivity and scalability across various networked environments. The integrated circuits of the computing system 1400 can include one or more CPUs and one or more GPUs.

FIG. 14 also demonstrates an example architecture of a multi-GPU architecture. As illustrated in the figure, computing system 1400 includes a processing device 1402 with a multi-GPU architecture. In particular, processing device 1402 may be a system-on-chip and includes multiple subsystems such as a CPU 1406, a GPU 1408, and a GPU 1410. CPU 1406 can be coupled to GPU 1408 via a die-to-die (D2D) or chip-to-chip (C2C) interconnect 1412, such as a Ground-Referenced Signaling interconnect (GRS interconnect). CPU 1406 can be coupled to GPU 1410 via a D2D or C2C interconnect 1414. CPU 1406 can also couple to GPU 1408 and GPU 1410 via PCIe interconnects.

CPU 1406 can be coupled to one or more NICs or DPUs, which are coupled to one or more networks. For example, as illustrated in FIG. 3, CPU 1406 is coupled to a first NIC/DPU 1426, which is coupled to a network 1430. CPU 1406 is also coupled to a second NIC/DPU 1428, which is coupled to network 1430 via switch 1448. NIC/DPU 1426 and NIC/DPU 1428 can be coupled to network 1430 over Ethernet (ETH), NVLINK or InfiniBand (IB) connections, for example.

Computing system 1400 also includes a processing device 1404 with a multi-GPU architecture. In particular, processing device 1404 includes multiple subsystems including a CPU 1416, a GPU 1418, and a GPU 1420. CPU 1416 can be coupled to GPU 1418 via an D2D or C2C interconnect 1422. CPU 1416 can be coupled to GPU 1420 via a D2D or C2C interconnect 1424. CPU 1416 can also couple to GPU 1418 and GPU 1420 via PCIe interconnects. CPU 1416 can be coupled to one or more NICs or DPUs, which are coupled to one or more networks. For example, as illustrated in FIG. 3, CPU 1416 is coupled to a first NIC/DPU 1432, which is coupled to a network 1436. CPU 1416 is also coupled to a second NIC/DPU 1434, which is coupled to network 1436 via switch 1450. NIC/DPU 1432 and NIC/DPU 1434 can be coupled to network 1436 over Ethernet (ETH), NVLINK or InfiniBand (IB) connections.

In at least one embodiment, processing device 1402 and processing device 1404 can communication with each other via a NIC/DPU 1438, such as over PCIe interconnects. Processing device 1402 and processing device 1404 can also communicate with each other over a high-bandwidth communication interconnects 1440, such as an NVLink interconnect or other high-speed interconnects. The packet switches in FIG. 3 may comprise, for example, Nvidia Quantum-2 switches. The NICs/DPUs in the figure may comprise, for example, Nvidia Bluefield DPUs.

In various embodiments, one or more of the interconnects 1412, 1414, 1422, 1424 may be optical interconnects disclosed herein. Additionally, in various embodiments, switches 1448, 1450 may be in communication with NIC/DPU 1428, 1432, respectively, via one or more optical interconnects disclosed herein. In some embodiments, NIC/DPU 1426, 1434 may be in communication with one or more additional elements via optical interconnects disclosed herein. For example, various elements of the computing system 1400 may be in communication with one another via one or more optical interconnects disclosed herein.

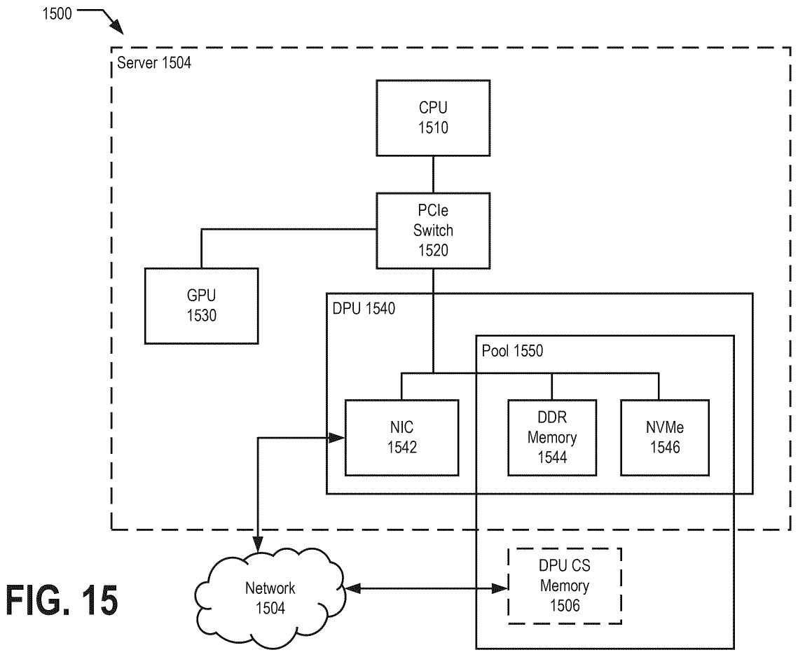

FIG. 15 illustrates an example computing environment 1500 in which forward pass offloading to available memory can be performed, in accordance with at least one embodiment. It should be appreciated that embodiments of the present disclosure may also be used with reference to alternative environments and that specific discussion of components may be provided by way of non-limiting example and may include equivalents. Moreover, various features have been removed for clarity and conciseness. Additionally, systems and methods may be used with a variety of different architectures. The example computing environment 1500 may include a server 1502 which may be used to perform high performance computing (HPC) workloads, such as AI training or machine learning model training. In an embodiment, the server 1502 may be an application instance or a compute node. The server 1502 may include a CPU 1510 associated with a switch 1520, such as a peripheral component interconnect express (PCIe) switch, which may control at least some data transmission over communication paths interconnecting various components. In an embodiment, the CPU 1510 may include a root complex processor.

The PCIe switch 1520 may also be associated with a GPU 1530 and a DPU 1540, and may transmit data between at least some of the CPU 1510, the GPU 1530, the DPU 1540, and other components (e.g., via one or more optical interconnects disclosed herein). In an embodiment, the PCIe switch 1520 may be associated with more than one GPU or more than one DPU. In another embodiment, the PCIe switch 1520 may be located within the DPU 1540. The PCIe switch 1520 may manage the transfer of at least some data between the CPU 1510, the GPU 1530, and the DPU 1540. In another embodiment, the number of GPUs associated with the PCIe switch 1520 may be equal to the number of DPUs associated with the PCIe switch 1520. In at least one embodiment, the server 1502 may include, without limitation, any number of the CPUs 1510, the PCIe switches 1520, the GPUs 1530, and/or the DPUs 1540, in any combination. For example, in at least one embodiment, server 1502 could include eight, sixteen, thirty-two, and/or more GPUs 1530. In at least one embodiment, communication paths interconnecting various components, including but not limited to the CPU 1510, the PCIe switch 1520, the GPU 1530, and the DPU 1540, in FIG. 15 may be implemented using any suitable protocols, such as peripheral component interconnect (PCI) based protocols (e.g., PCIe), or other bus or point-to-point communication interfaces and/or protocol(s), such as NV-Link high-speed interconnect, or interconnect protocols.

The DPU 1540 may include a network interface controller (NIC) 1542, a DDR memory 1544, and a non-volatile memory express (NVMe) device 1546. The NIC 1542 may be able to interface with a network 1504, which may also interface with additional NVMe devices available to the DPU 1540, such as over fabric. In an embodiment, the DPU 1540 may not include the NVMe device 1546. In another embodiment, the NVMe device 1546 may be located on the server 1502 and not on the DPU 1540. In yet another embodiment, the computing environment 1500 may include more than one of the NVMe device 1546, such as a first NVMe device in the DPU 1540 and a second first NVMe device on the server 1502 an associated directly with the PCIe switch 1520. In an embodiment, the DPU 1540 may not include the DDR memory 1544 and may include a computational storage services (CSS) in place of, or in addition to, the DDR memory 1544. For example, computing environment 1500 may include DPU computational storage (CS) memory 1506 available to the DPU 1540 as part of the CSS. The network 1504 may be able to interface with the DPU CS memory 1506 through the NIC 1542, according to any suitable interface protocol, such as remote direct memory access (RDMA) over Ethernet, InfiniBand, Fiber Channel, etc.

The total memory of the computing environment 1500 available for data storage may be expanded through the use of the DPU 1540 on nodes of the system. The DPU 1540 may have access to a pool 1550 of memory already available to the server 1502, such as double data rate (DDR) memory, on-board NVMe devices, NVMe devices over fabric, and CS. The pool 1550 of memory may include at least one of the DDR memory 1544, NVMe 1546, and the DPU CS memory 1506. The DPU 1540 may also be able to access the available memory of other DPUs as part of the pool 1550, and other DPUs may be able to access the available memory of DPU 1540, such as the pool 1550. This available memory can be accessed and utilized for data storage, without the addition of compute resources, such as compute nodes, which would be required using other solutions. The available pool 1550 accessible to the DPU 1540 may be provisioned for the server 1502 to expand the total memory available for data storage, such as to reduce the data storage load on the CPU 1510 or the GPU 1530, which can instead increase the utilization of their memory for processing. For example, during training of an AI, the model states, residual states, activation functions, and checkpoints can be stored, or offloaded, on the pool 1550 accessible to the DPU 1540.

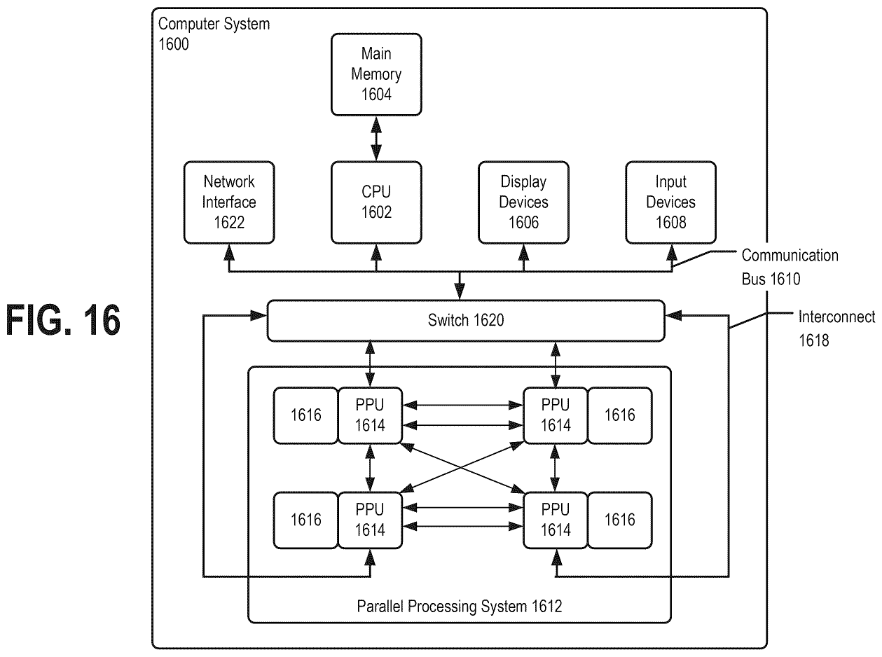

FIG. 16 illustrates a computer system 1600, according to at least one embodiment. In at least one embodiment, computer system 1600 comprises at least one optical interconnect of an example embodiment.

In at least one embodiment, computer system 1600 comprises, without limitation, at least one central processing unit (“CPU”) 1602 that is connected to a communication bus 1610 implemented using any suitable protocol, such as PCI (“Peripheral Component Interconnect”), peripheral component interconnect express (“PCI-Express”), AGP (“Accelerated Graphics Port”), HyperTransport, or any other bus or point-to-point communication protocol(s). In at least one embodiment, computer system 1600 includes, without limitation, a main memory 1604 and control logic (e.g., implemented as hardware, software, or a combination thereof) and data are stored in main memory 1604 which may take form of random access memory (“RAM”). In at least one embodiment, a network interface subsystem (“network interface”) 1622 provides an interface to other computing devices and networks for receiving data from and transmitting data to other systems from computer system 1600.

In at least one embodiment, computer system 1600, in at least one embodiment, includes, without limitation, input devices 1608, parallel processing system 1612, and display devices 1606 which can be implemented using a conventional cathode ray tube (“CRT”), liquid crystal display (“LCD”), light emitting diode (“LED”), plasma display, or other suitable display technologies. In at least one embodiment, user input is received from input devices 1608 such as keyboard, mouse, touchpad, microphone, and more. In at least one embodiment, each of foregoing modules can be situated on a single semiconductor platform to form a processing system.

In at least one embodiment, computer programs in form of machine-readable executable code or computer control logic algorithms are stored in main memory 1604 and/or secondary storage. Computer programs, if executed by one or more processors, enable system 1600 to perform various functions in accordance with at least one embodiment. memory 1604, storage, and/or any other storage are possible examples of computer-readable media. In at least one embodiment, secondary storage may refer to any suitable storage device or system such as a hard disk drive and/or a removable storage drive, representing a floppy disk drive, a magnetic tape drive, a compact disk drive, digital versatile disk (“DVD”) drive, recording device, universal serial bus (“USB”) flash memory, etc. In at least one embodiment, architecture and/or functionality of various previous figures are implemented in context of CPU 1602; parallel processing system 1612; an integrated circuit capable of at least a portion of capabilities of both CPU 1602; parallel processing system 1612; a chipset (e.g., a group of integrated circuits designed to work and sold as a unit for performing related functions, etc.); and any suitable combination of integrated circuit(s).

In at least one embodiment, architecture and/or functionality of various previous figures are implemented in context of a general computer system, a circuit board system, a game console system dedicated for entertainment purposes, an application-specific system, and more. In at least one embodiment, computer system 1600 may take form of a desktop computer, a laptop computer, a tablet computer, servers, supercomputers, a smart-phone (e.g., a wireless, hand-held device), personal digital assistant (“PDA”), a digital camera, a vehicle, a head mounted display, a hand-held electronic device, a mobile phone device, a television, workstation, game consoles, embedded system, and/or any other type of logic.

In at least one embodiment, parallel processing system 1612 includes, without limitation, a plurality of parallel processing units (“PPUs”) 1614 and associated memories 1616. In at least one embodiment, PPUs 1614 are connected to a host processor or other peripheral devices via an interconnect 1618 and a switch 1620 or multiplexer. In at least one embodiment, parallel processing system 1612 distributes computational tasks across PPUs 1614 which can be parallelizable—for example, as part of distribution of computational tasks across multiple graphics processing unit (“GPU”) thread blocks. In at least one embodiment, memory is shared and accessible (e.g., for read and/or write access) across some or all of PPUs 1614, although such shared memory may incur performance penalties relative to use of local memory and registers resident to a PPU 1614. In at least one embodiment, operation of PPUs 1614 is synchronized through use of a command such as_syncthreads(), wherein all threads in a block (e.g., executed across multiple PPUs 1614) to reach a certain point of execution of code before proceeding.

The PPUs 1614 may be in communication with one another and/or switch 1620 via one or more optical interconnects in accordance with example embodiments disclosed herein.

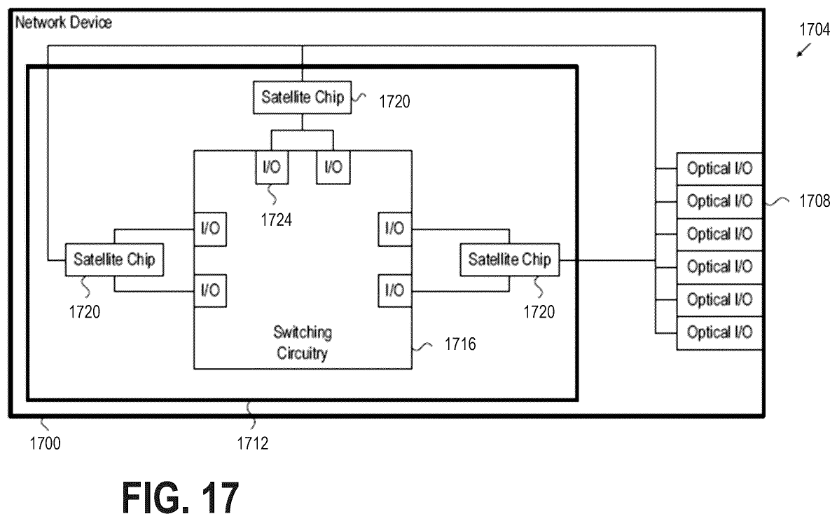

Co-packaging may refer to the close integration of different electrical and/or optoelectronic chips in the same package. FIG. 17 is a block diagram that schematically illustrates a co-packaged Networking Device 1700, in accordance with an embodiment that is disclosed herein. The different chips that constitute a co-packaged Networking Device are assembled on a single substrate in what is typically called the MCM assembly 1712. The MCM assembly 1712 can include a switching circuitry 1716 surrounded by peripheral or satellite chips 1720. In some embodiments, the switching circuitry 1716 and surrounding satellite chips 1720 are all mounted on a common substrate, although such a configuration is not required. The MCM assembly 1712 may be provided in a larger housing of the networking device 1712, positioned behind the front panel 1704. The switching circuitry 1716 may include one or more core digital Application Specific Integrated Circuits (ASICs), CPUs, GPUs, microprocessors, FPGAs, combinations thereof, and the like. The switching circuitry 1716 may include a number of input ports and/or output ports 1728. The Input/Output (I/O) ports 1724 may include electrical ports and/or optical ports. Additionally, the switching circuitry 1716 may include a combination of electrical blocks and optical blocks. The electrical blocks of the switching circuitry 1716 may include a number of electrical switches that are configured to route signals in an electrical domain. The optical blocks of the switching circuitry 1716 may include a number of optical components that are configured to generate, detect, and route signals in an optical domain. The MCM assembly 1712, in some embodiments, may concern or include multiple satellite chips 1720 that are assembled on the same substrate as the switching circuitry 1716. In some embodiments, a configuration of the optical block(s) and a configuration of the electrical block(s) depends (e.g., is based on) on the number of optical ports in the I/O ports 1724.

As discussed above, optical I/Os 1708, which may also be referred to as optical connectors, are placed at the front panel 1704. As mentioned above, connectivity between the MCM assembly 1712 and optical I/Os 1708 may be transferred to the front panel 1704 through optical fibers. This connection may be made directly with an optical I/O 1724 of the switching circuitry or may be made with one or more of the satellite chips 1720. The connection is often made with one or more of the satellite chips 1720 because the satellite chips 1720 may include the electro-optic converters and, possibly, the serializer/deserializer (SERDES) to natively support the connection. The satellite chips 1720 may include one or more of aDSP processor, driver, trans-impedance amplifier, laser, modulator, photodiode, serializer-deserializer, or the like.

Some embodiments of the present disclosure are directed to a multi-chip module (MCM) with a centrally positioned main die and a plurality of peripherally positioned MCM sockets configured to mechanically receive and electrically connect mezzanine packages, which may include co-packaged optics (CPO) packages and co-packaged copper (CPC) packages. Each mezzanine package may include a package substrate including a connector portion that is configured to engage the MCM socket and a main portion extending beyond the periphery of the MCM substrate. The main portion of the mezzanine package may be configured to receive optical devices and/or integrated circuits, such as via mezzanine sockets, to allow connections to be made between the optical devices and/or integrated circuits/RF copper cable connectors and the main die of the MCM. Due to the extension of the mezzanine package beyond the periphery of the MCM substrate, the physical size of the MCM substrate may remain small to reduce cost and avoid the previously discussed production challenges, while allowing connections to a number of optical devices and integrated circuits via the mezzanine packages, which occupy the relatively inexpensive space around the periphery of the MCM substrate. As used herein, the terms “co-packaged optic” (or “CPO”) and “co-packaged copper” (or “CPC”) may refer to an advanced heterogeneous integration of either optics and silicon or copper and silicon, in which either integration may be implemented on a single packaged substrate. The CPO may utilize pluggable optical modules that include an optical engine (OE) to convert optical signals to electrical signals and electrical signals to optical signals. The CPO may further be comprised of an optical component on a photonics die and an electrical component on an electrical die.

As used herein, a ball grid array (BGA) may be a type of surface-mount packaging used for integrated circuits. BGA packages use an array of metallic conductor balls arranged in a grid to permanently mount devices such as microprocessors on a PCB. The metallic conductor balls may then undergo the reflow process described above, wherein the metallic conductor balls may be preheated, then melted to bond the IC to a substrate to form an IC package.

As used herein, the term “flip chip (FC)” may refer to a method for interconnecting dies, such as semiconductor devices, IC chips, integrated passive devices, and microelectromechanical systems (MEMS), to external circuitry with solder bumps that have been deposited onto chip pads. The solder bumps may be deposited onto chip pads on the top side of the wafer during final wafer processing. The chip may be mounted to external circuitry (such as a circuit board or another chip or wafer) by “flipping” the chip, such that the chip's top side faces down and is positioned to allow the pads of the chip to align with matching pads on the external circuit. Solder is reflowed to complete the interconnect.

### Conclusion

Many modifications and other embodiments will come to mind to one skilled in the art to which this disclosure pertains having the benefit of the teachings presented in the foregoing descriptions and the associated drawings. Therefore, it is to be understood that the disclosure is not to be limited to the specific embodiments disclosed and that modifications and other embodiments are intended to be included within the scope of the appended claims. Although specific terms are employed herein, they are used in a generic and descriptive sense only and not for purposes of limitation.

1. A heat-managed (HM) device comprising:
a semiconductor device comprising III-V semiconductor material, wherein operation of the semiconductor device generates heat; and
a film of a thermally conductive material disposed at least on a perimeter of the semiconductor device and directly in thermal communication with semiconductor material of the semiconductor device, wherein the thermally conductive material is characterized by an in-plane thermal conductivity coefficient and an out-of-plane thermal conductivity coefficient and the out-of-plane thermal conductivity coefficient is less than the in-plane thermal conductivity coefficient.

2. The HM device of claim 1, wherein the film is further disposed on at least a portion of an end of a mesa of the semiconductor device.

3. The HM device of claim 1, wherein the film is in direct physical contact with the semiconductor material.

4. The HM device of claim 1, wherein the semiconductor device is one of a vertical cavity surface emitting laser (VCSEL), distributed-feedback (DFB) laser, electro-absorption modulated laser (EML), modulator, light emitting diode (LED), diode, or a power transistor.

5. The HM device of claim 1, wherein the film comprises a first film that is thermally conductive and electrically non-conductive and a second film that is thermally conductive, and the first film is in direct contact with the semiconductor material of the semiconductor device.

6. The HM device of claim 1, wherein the film is electrically non-conductive and the film is a passivation layer on the semiconductor device.

7. The HM device of claim 1, wherein the thermally conductive, electrically non-conductive material is two-dimensional hexagonal boron nitride (2D h-BN) or aluminum nitride (AlN).

8. The HM device of claim 1, wherein the film has a thickness in a range of one atomic layer to 300 nm.

9. The HM device of claim 1, wherein the film is in thermal communication with a heat sink.

10. The HM device of claim 1, wherein the in-plane thermal conductivity coefficient is at least 400 W/m*K.

11. The HM device of claim 1, wherein a topology of the film is defined by a topology of the semiconductor device.

12. An array of heat-managed (HM) devices comprising:
an array of a plurality of semiconductor devices, wherein operation of a semiconductor device of the plurality of semiconductor devices generates heat, wherein the semiconductor device has a film of a thermally conductive material disposed at least on a perimeter of the semiconductor device and directly in thermal communication with semiconductor material of the semiconductor device, wherein the thermally conductive material is characterized by an in-plane thermal conductivity coefficient and an out-of-plane thermal conductivity coefficient and the out-of-plane thermal conductivity coefficient is less than the in-plane thermal conductivity coefficient.

13. The array of HM devices of claim 12, wherein the film is further disposed on an end of a mesa of the semiconductor device.

14. The array of HM devices of claim 12, wherein the plurality of semiconductor devices comprise at least one of a vertical cavity surface emitting laser (VCSEL), distributed-feedback (DFB) laser, light emitting diode (LED), electro-absorption modulated laser (EML), modulator, diode, or a power transistor.

15. The array of HM devices of claim 12, wherein the film comprises a first film that is thermally conductive and electrically non-conductive and a second film that is thermally conductive, and the first film is in direct contact with the semiconductor material of the semiconductor device.

16. The array of HM devices of claim 12, wherein the thermally conductive material is electrically non-conductive and is a passivation layer on the semiconductor device.

17. The array of HM devices of claim 12, wherein the thermally conductive material is two-dimensional hexagonal boron nitride (2D h-BN) or aluminum nitride (AlN).

18. The array of HM devices of claim 12, wherein the film has a thickness in a range of one atomic layer to 300 nm.

19. The array of HM devices of claim 12, wherein the array of devices in in thermal communication with a heat sink via the film.

20. The array of HM devices of claim 12, wherein the in-plane thermal conductivity coefficient is at least 400 W/m*K.

21. A method for fabricating a heat-managed (HM) device, the method comprising:
fabricating one or more semiconductor components of a semiconductor device, wherein fabricating the one or more semiconductor components of the semiconductor device comprises defining a perimeter of the semiconductor device; and
transferring or depositing a film of thermally conductive material onto the perimeter of the semiconductor device, wherein the thermally conductive material is characterized by an in-plane thermal conductivity coefficient and an out-of-plane thermal conductivity coefficient and the out-of-plane thermal conductivity coefficient is less than the in-plane thermal conductivity coefficient.

22. The method of claim 21, further comprising growing the film on a foil, covering the film with poly(methyl methacrylate) (PMMA), and removing the foil.

23. The method of claim 22, further comprising transferring the film to the perimeter of the semiconductor device, and removing the PMMA.

24. The method of claim 23, further comprising at least one of depositing Benzocyclobutene (BCB) or another structural material on the film or performing a lithographic process.

25. The method of claim 21, wherein transferring the film of thermally conductive material onto the perimeter of the semiconductor device transfers a topology of the semiconductor device to the film.

26. The method of claim 21, wherein transferring or depositing the film comprises performing an atomic layer deposition (ALD) of the film.

27. An optical interconnect comprising:
a first transceiver;
a second transceiver; and
an optical fiber in optical communication with the first transceiver and the second transceiver,
wherein at least one of the first transceiver or the second transceiver comprises a heat-managed (HM) device or an array of HM devices where each HM device comprises:
a semiconductor device comprising III-V semiconductor material, wherein operation of the semiconductor device generates heat; and
a film of a thermally conductive disposed at least on a perimeter of the semiconductor device and directly in thermal communication with semiconductor material of the semiconductor device, wherein the thermally conductive material is characterized by an in-plane thermal conductivity coefficient and an out-of-plane thermal conductivity coefficient and the out-of-plane thermal conductivity coefficient is less than the in-plane thermal conductivity coefficient.
